(19) United States
(12) Patent Application Publication
(10) Pub. No.: US 2019/0096632 A1
(43) Pub. Date: Mar. 28, 2019

(54) CHARGED PARTICLE BEAM IRRADIATION APPARATUS AND METHOD FOR REDUCING ELECTRIFICATION OF SUBSTRATE

(71) Applicant: NuFlare Technology, Inc., Yokohama-shi (JP)

(72) Inventor: Munehiro OGASAWARA, Hiratsuka-shi (JP)

(73) Assignee: NuFlare Technology, Inc., Yokohama-shi (JP)

(21) Appl. No.: 16/104,210

(22) Filed: Aug. 17, 2018

(30) Foreign Application Priority Data
Sep. 26, 2017 (JP) 2017-185151

(51) Int. Cl. H01J 37/30; H01J 37/317; H01J 37/141

(52) U.S. Cl. CPC H01J 37/3007; H01J 37/3174; H01J 37/141; H01J 37/3177; H01J 2237/31776; H01J 2237/04922; H01J 2237/141; H01J 2237/083; H01J 2237/31774; H01J 2237/0044

(57) ABSTRACT

According to one aspect of the present invention, a charged particle beam irradiation apparatus includes: a plurality of electrodes arranged in a magnetic field space of an electromagnetic lens and also arranged so as to surround a space on an outer side of a passing region of a charged particle beam; and a potential control circuit configured to control potentials of the plurality of electrodes so as to generate plasma in the space surrounded by the plurality of electrodes and so as to control movement of positive ions or electrons and negative ions generated by the plasma, wherein positive ions, electrons and negative ions, or active species are emitted from the space of the plasma.

### CROSS-REFERENCE TO RELATED APPLICATION

This application is based upon and claims the benefit of priority from prior Japanese Patent Application No. 2017-185151 filed on Sep. 26, 2017 in Japan, the entire contents of which are incorporated herein by reference.

### BACKGROUND OF THE INVENTION

### Field of the Invention

Embodiments described herein relate generally to a charged particle beam irradiation apparatus and a method for reducing electrification of a substrate and relates to, for example, a method for reducing electrification generated on a substrate due to irradiation with an electron beam.

### Related Art

In recent years, with an increase in integration density of an LSI, a circuit line width of semiconductor devices is getting still smaller. As a method for forming an exposure mask (also referred to as a reticle) to form a circuit pattern on these semiconductor devices, an electron beam (EB) lithography technique having excellent resolution is used.

FIG. 28 is a conceptual diagram illustrating an operation of a variable-shaped electron beam lithography apparatus. The variable-shaped electron beam lithography apparatus operates as described below. A rectangular opening 411 to shape an electron beam 330 is formed in a first aperture plate 410. A variable-shaped opening 421 to shape the electron beam 330 having passed through the opening 411 of the first aperture plate 410 into a desired rectangular shape is formed in a second aperture plate 420. The electron beam 330 irradiated from a charged particle source 430 and having passed through the opening 411 of the first aperture plate 410 is deflected by a deflector and passes through a portion of the variable-shaped opening 421 of the second aperture plate 420 before a target object 340 placed on a stage continuously moving in a predetermined direction (for example, the X direction) being irradiated therewith. That is, a rectangular shape capable of passing through both the opening 411 of the first aperture plate 410 and the variable-shaped opening 421 of the second aperture plate 420 is written in a pattern writing region of the target object 340 placed on the stage continuously moving in the X direction. The method for forming any shape by causing a beam to pass through both the opening 411 of the first aperture plate 410 and the variable-shaped opening 421 of the second aperture plate 420 is called the variable-shaped beam method (VSB method).

Irradiating a substrate with an electron beam causes a problem that the upper surface of the substrate is charged. Electrification of the substrate surface leads to deterioration in writing accuracy. Thus, in order to eliminate such electrification, passing an ion gas for neutralization onto the substrate is considered. In addition, contaminants such as particles adhering to the substrate and the like cause deterioration in writing accuracy. In order to remove such contaminants, discharging plasma or the like onto the substrate is considered. Such a problem occurs not only in an electron beam lithography apparatus, but also in an apparatus for irradiating a target object with an electron beam such as an electron microscope and an electron beam inspection apparatus. For example, arranging an ion and plasma generating apparatus for supplying an ion gas in a chamber of a scanning electron microscope (SEM) is disclosed (see Japanese Unexamined Patent Application Publication No. 2007-149449, for example). However, if an ion generating apparatus is arranged near or inside an apparatus that emits an electron beam, the scale of the apparatus becomes large. In addition, when such an ion generating apparatus generates a magnetic field, problems such as a magnetic field generated by an electromagnetic lens constituting an original electron beam optical system of the electron beam lithography apparatus being likely to be affected may occur.

### BRIEF SUMMARY OF THE INVENTION

According to one aspect of the present invention, a charged particle beam irradiation apparatus includes:

an emission source configured to emit a charged particle beam;

an electromagnetic lens configured to refract the charged particle beam;

a plurality of electrodes arranged in a magnetic field space of the electromagnetic lens and also arranged so as to surround a space on an outer side of a passing region of the charged particle beam; and

a potential control circuit configured to control potentials of the plurality of electrodes so as to generate plasma in the space surrounded by the plurality of electrodes and so as to control movement of positive ions or electrons and negative ions generated by the plasma, wherein

positive ions, electrons and negative ions, or active species are emitted from the space of the plasma.

According to another aspect of the present invention, a method for reducing electrification includes:

controlling potentials of a plurality of electrodes arranged in a magnetic field space of an objective lens that focuses a charged particle beam on a substrate surface and also arranged so as to surround a space on an outer side of a passing region of the charged particle beam to cause the plurality of electrodes to generate plasma in the space surrounded by the plurality of electrodes and also to control movement of positive ions or electrons and negative ions generated by the plasma; and

reducing electrification of the substrate by allowing to emit the positive ions or the electrons and negative ions from the space of the plasma toward the substrate.

### BRIEF DESCRIPTION OF THE DRAWINGS

FIG. 1 is a conceptual diagram showing a configuration of a lithography apparatus according to Embodiment 1;

FIG. 2 is a conceptual diagram illustrating each region in Embodiment 1;

FIG. 3 is a diagram showing an example of a state of a magnetic field generated by an electromagnetic lens according to Embodiment 1;

FIG. 4 is a sectional view showing an example of the configuration near an objective lens in Embodiment 1;

FIG. 5 is a sectional view showing another example of the configuration near the objective lens in Embodiment 1;

FIG. 6 is a top view when a state in which a plurality of electrodes according to Embodiment 1 is arranged is viewed from above an upper electrode;

FIG. 7 is a top view when the state in which the plurality of electrodes according to Embodiment 1 is arranged is viewed from an intermediate height position of an outer electrode;

FIG. 8 is a top view of a lower electrode of the plurality of electrodes according to Embodiment 1;

FIG. 9 is a flow chart showing principal processes of a method for reducing electrification according to Embodiment 1;

FIG. 10 is a sectional view showing still another example of the configuration near the objective lens in Embodiment 1;

FIG. 11 is a sectional view showing still another example of the configuration near the objective lens in Embodiment 1;

FIG. 12 is a sectional view showing still another example of the configuration near the objective lens in Embodiment 1;

FIG. 13 is a sectional view showing still another example of the configuration near the objective lens in Embodiment 1;

FIG. 14 is a sectional view showing still another example of the configuration near the objective lens in Embodiment 1;

FIG. 15 is a sectional view showing still another example of the configuration near the objective lens in Embodiment 1;

FIG. 16 is a sectional view showing still another example of the configuration near the objective lens in Embodiment 1;

FIG. 17 is a top view when an example of the configuration near the objective lens according to a modification of Embodiment 1 is viewed from a height position between the upper electrode and the lower electrode;

FIG. 18 is a diagram illustrating generation of plasma in the configuration near the objective lens in the modification of Embodiment 1;

FIG. 19 is a sectional view showing an example of the configuration near the objective lens in Embodiment 2;

FIG. 20 is a diagram illustrating an electric field and an electron trajectory in Embodiment 2;

FIG. 21 is a sectional view showing another example of the configuration near the objective lens in Embodiment 2;

FIG. 22 is a top view when an example of the configuration near the objective lens according to a modification of Embodiment 2 is viewed from the height position between the upper electrode and the lower electrode;

FIG. 23 is a sectional view showing an example of the configuration near the objective lens in Embodiment 3;

FIG. 24 is a sectional view showing another example of the configuration near the objective lens in Embodiment 3;

FIG. 25 is a sectional view showing still another example of the configuration near the objective lens in Embodiment 3;

FIG. 26 is a conceptual diagram showing the configuration of a lithography apparatus according to Embodiment 4;

FIG. 27 is a sectional view showing a modification of the configuration in FIG. 5; and

FIG. 28 is a conceptual diagram illustrating an operation of a variable-shaped electron beam lithography apparatus.

### DETAILED DESCRIPTION OF THE INVENTION

In Embodiments described below, an apparatus and a method capable of reducing charging or/and removing contaminants without affecting a magnetic field generated by an electromagnetic lens constituting a charged particle beam optical system inherent to the apparatus that emits a charged particle beam will be described.

In Embodiments described below, the configuration using an electron beam will be described as an example of a charged particle beam. However, the charged particle beam is not limited to an electron beam, and a beam such as an ion beam using charged particles may also be used. Also, an electron beam lithography apparatus will be described as an example of a charged particle beam irradiation apparatus. However, the charged particle beam irradiation apparatus is not limited to a lithography apparatus and may be any apparatus that uses an electromagnetic lens in an optical system and emits a charged particle beam such as an electron microscope or an electron beam inspection apparatus. Further, as an example of the electron beam lithography apparatus, a variable-shaped beam type lithography apparatus and a multiple-beam lithography apparatus will be described.

### Embodiment 1

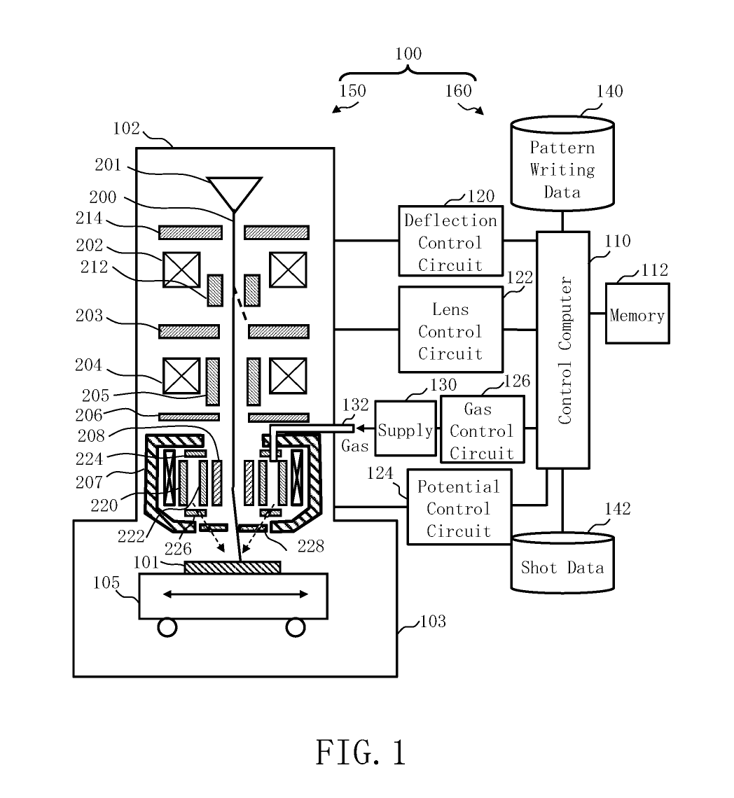

FIG. 1 is a conceptual diagram showing the configuration of a lithography apparatus according to Embodiment 1. In FIG. 1, a lithography apparatus 100 includes a pattern writing mechanism 150 and a control system circuit 160. The lithography apparatus 100 is an example of the electron beam lithography apparatus. In particular, the lithography apparatus 100 is an example of a variable-shaped beam type (VSB type) lithography apparatus. The pattern writing mechanism 150 includes an electron optical column (electron beam column) 102, a pattern writing chamber 103, and a gas supply device 130. In the electron optical column 102, an electron gun assembly 201, an illumination lens 202, a blanking deflector (blanker) 212, a beam limiting aperture plate substrate 214, a first shaping aperture plate substrate 203, a projection lens 204, a deflector 205, a second shaping aperture plate substrate 206, an objective lens 207, a deflector 208, electrodes 220, 222, 224, 226, a retarding electrode 228, and a gas supply line 132 are arranged. Inside the pattern writing chamber 103, an XY stage 105 capable of moving at least in the X and Y directions is arranged. A substrate 101 (target object) to be written to and coated with a resist is arranged on the XY stage 105. The substrate 101 includes an exposure mask, a silicon wafer and the like for manufacturing a semiconductor device. The mask includes mask blanks. Incidentally, the inside of the electron optical column 102 and the pattern writing chamber 103 is evacuated by a vacuum pump (not shown), and is kept in a pressure state sufficiently lower than the atmosphere (so-called vacuum state).

The control system circuit 160 has a control computer 110, a memory 112, a deflection control circuit 120, a lens control circuit 122, a potential control circuit 124, a gas control circuit 126, and storage devices 140, 142 such as a magnetic disk drive. The control computer 110, the memory 112, the deflection control circuit 120, the lens control circuit 122, the potential control circuit 124, the gas control circuit 126, and the storage devices 140, 142 are mutually connected via a bus (not shown). The deflector 208 is connected to the deflection control circuit 120 and controlled. Also, though not shown, the blanking deflector 212 and the deflector 205 are connected to the deflection control circuit 120 and controlled. The objective lens 207 is connected to the lens control circuit 122 and controlled. Also, though not shown, the illumination lens 202 and the projection lens 204 are connected to the lens control circuit 122 and controlled. The electrodes 220, 222, 224, 226 are connected to the potential control circuit 124 and controlled. Also, the potentials of the substrate 101 and the retarding electrode 228 are controlled by a power supply device (not shown) or the like.

Necessary input data or computed results in the control computer 110 are stored in the memory 112 each time.

Pattern writing data (chip data) in which data of a chip pattern is defined is input from outside the lithography apparatus 100 and stored in the storage device 140.

Here, in FIG. 1, only the configuration needed to describe Embodiment 1 is shown. Other configurations normally needed for the lithography apparatus 100 may also be included.

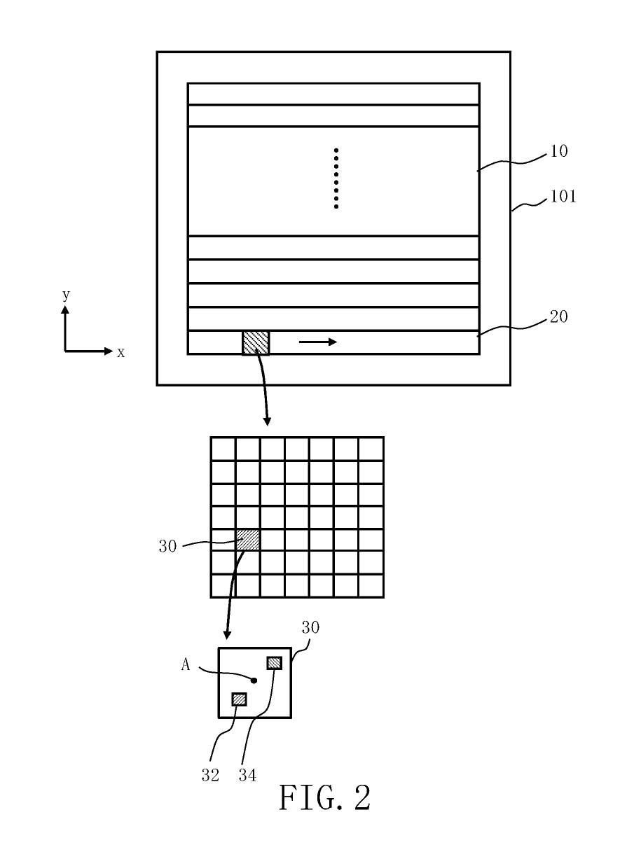

FIG. 2 is a conceptual diagram illustrating each region in Embodiment 1. In FIG. 2, a pattern writing region 10 of the substrate 101 is virtually divided into a plurality of stripe regions 20 in a thin rectangular shape, for example, in the y direction in a width deflectable by the deflector 208. Each stripe region 20 is virtually divided into a plurality of subfields (SF) 30 (sub deflection regions) in a mesh shape. Then, shot FIGS. 32, 34 are written to each shot position of each of the SF 30.

When a pattern writing process is performed, the control computer 110 controls the deflection control circuit 120, the lens control circuit 122, the potential control circuit 124, the gas control circuit 126, the pattern writing mechanism 150 and the like to start the pattern writing process. The control computer 110 reads the chip data (pattern writing data) stored in the storage device 140 and divides a plurality of figure patterns in the chip data into a plurality of shot figures of a size that can be shaped by the lithography apparatus 100 for each figure pattern to generate shot data for each shot figure. The shot data defines the figure type, the shot position coordinates of the figure, the shot size, and the like. The generated shot data is stored in the storage device 142. Then, the pattern writing mechanism 150 writes a pattern to each shot position using the electron beam 200 under the control of the deflection control circuit 120 and the lens control circuit 122. A more specific operation is as described below.

The current distribution of the electron beam 200 emitted from the electron gun assembly 201 (emission source) is limited to the vicinity of the distribution center by the beam limiting aperture plate substrate 214, and when passing through the blanking deflector 212, for example, a portion of the electron beam 200 is controlled by the blanking deflector 212 to pass through the opening provided in the first shaping aperture plate substrate 203 in the beam ON state, and the electron beam 200 is deflected such that none thereof passes through the opening provided in the first shaping aperture plate substrate 203 and the electron beam is totally blocked by the first shaping aperture plate substrate 203 in the beam OFF state. The duration between the two consecutive changes of state, a change from the beam off state to the beam on state and a change from the beam on state to the beam off state, is the duration of one shot of electron beam. The blanking deflector 212 controls the direction of the passing electron beam 200 to alternately generate the beam ON state and the beam OFF state. For example, no voltage is applied in the beam ON state, and a voltage may be applied to the blanking deflector 212 when the beam is OFF. The dose per shot of the electron beam 200 with which the substrate 101 is irradiated is adjusted in the beam irradiation time of each shot.

In the beam ON state, as described above, the electron beam 200 having passed through the beam limiting aperture plate substrate 214 and the blanking deflector 212 illuminates the entire first shaping aperture plate substrate 203 having a rectangular hole through the illumination lens 202. Here, the electron beam 200 is first shaped into a rectangular shape. Then, the electron beam 200 of a first aperture plate image having passed through the first shaping aperture plate substrate 203 is projected onto the second shaping aperture plate substrate 206 by the projection lens 204. The first aperture plate image on the second shaping aperture plate substrate 206 is controlled to deflect by the deflector 205 so that the beam shape and dimensions can be changed (variably shaped). Such variable shaping is performed for each shot and beam shapes and dimensions are normally different for each shot. Then, the electron beam 200 passing through the second aperture plate is focused on the surface of the substrate 101 by the objective lens 207 so that the cross section of the electron beam 200 passing through the second aperture plate is imaged on the substrate 101. This is called. Then, the electron beam 200 is deflected to irradiate a desired position on the surface of the substrate 101 by the deflector 208. In other words, the electron beam 200 is irradiated on a desired position of the substrate 101 placed on the continuously moving XY stage 105. As described above, a plurality of shots of the electron beam 200 is successively made on the substrate 101. As described above, the electron beam 200 proceeds to the surface of substrate 101 while being refracted by each electromagnetic lens such as the illumination lens 202, the projection lens 204, and the objective lens 207.

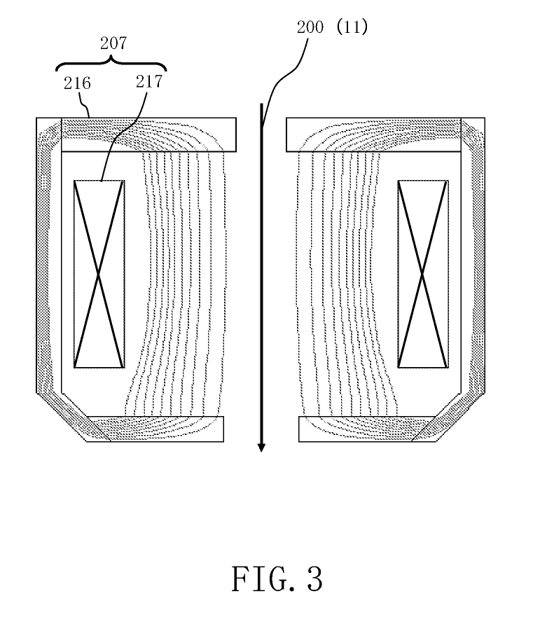

FIG. 3 is a diagram showing examples of magnetic field lines (lines of magnetic force) generated by the electromagnetic lens according to Embodiment 1. Each electromagnetic lens such as the illumination lens 202, the projection lens 204, and the objective lens 207 is constructed of a coil disposed so as to surround the optical axis of the electron beam 200 and a pole piece (yoke) surrounding the coil. In the pole piece (yoke), an opening portion (also referred to as a gap) for causing a high-density line of magnetic force generated by the coil to leak to the optical axis side of the electron beam 200 is formed. Here, as an example, the objective lens 207 will be described. In FIG. 3, the objective lens 207 has a pole piece (yoke) 216 and a coil 217. The pole piece 216 is formed in a vertically long shape (long on the optical axis side), and the coil 217 formed in a vertically long shape is arranged inside. The central portion of the upper and lower surfaces of the pole piece 216 is opened so as to secure a passing region of the electron beam and the pole piece 216 has a shape opened toward the optical axis side of the electron beam 200 (an opening portion is formed). The coil 217 is disposed at a position close to the outer circumferential side inside a space surrounded by the pole piece 216 in three directions of the upper and lower surfaces and the outer circumferential surface. In such a state, by passing a current toward the coil 217, the coil 217 generates lines of magnetic force in the traveling direction of the electron beam 200 (downward in FIG. 3) in a space on the inner side (optical axis side) of the coil 217. In the example of FIG. 3, in a section on the right-hand side of an optical axis 11 of the electron beam 200, the lines of magnetic force generated by the coil 217 turn counterclockwise inside the pole piece 216. Then, a loop is formed by advancing lines of magnetic force from an upper surface optical axis side end of the pole piece 216 to a lower surface optical axis side end through an open space on the optical axis side. In the section on the left-hand side of the optical axis 11 of the electron beam 200, on the contrary, lines of magnetic force generated by the coil 217 turn clockwise inside the pole piece 216. Then, a loop is formed by advancing lines of magnetic force from an upper surface optical axis side end of the pole piece 216 to a lower surface optical axis side end through an open space on the optical axis side. As described above, a magnetic field is generated in a traveling direction of the electron beam 200 (downward in FIG. 3) in a space on an inner side (on the optical axis side) of the coil 217. Therefore, in Embodiment 1, by generating plasma using a magnetic field generated in the space on the inner side (optical axis side) of the coil 217, a gas of ions or/and active species is generated.

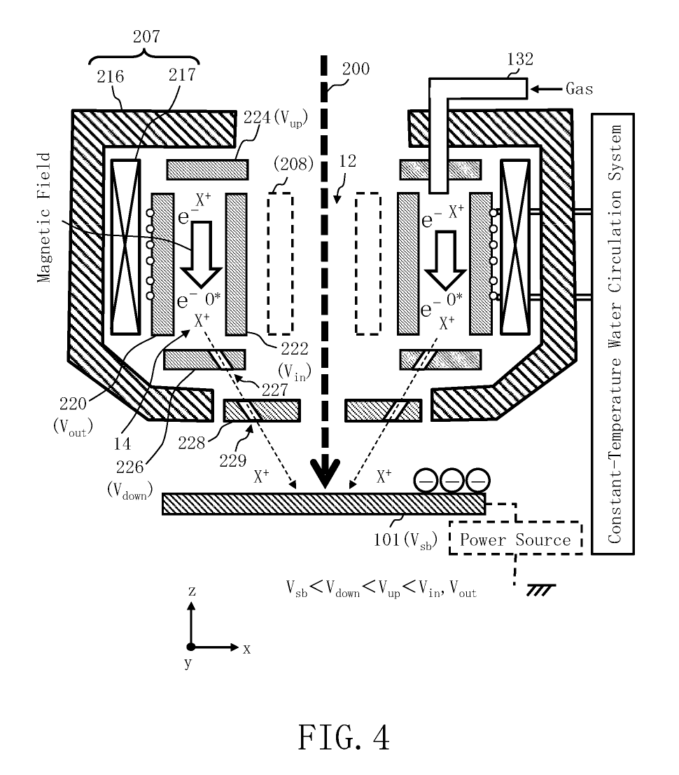

FIG. 4 is a sectional view showing an example of the configuration near an objective lens in Embodiment 1. In FIG. 4, a plurality of electrodes such as the outer electrode 220, the inner electrode 222, the upper electrode 224, and the lower electrode 226 is arranged in the magnetic field space on the inner side (the optical axis side) of the coil 217 inside the pole piece 216 of the objective lens 207. As shown in FIG. 4, the plurality of electrodes such as the outer electrode 220, the inner electrode 222, the upper electrode 224, and the lower electrode 226 is arranged so as to surround a space 14 on the outer side of a passing region 12 of the electron beam 200.

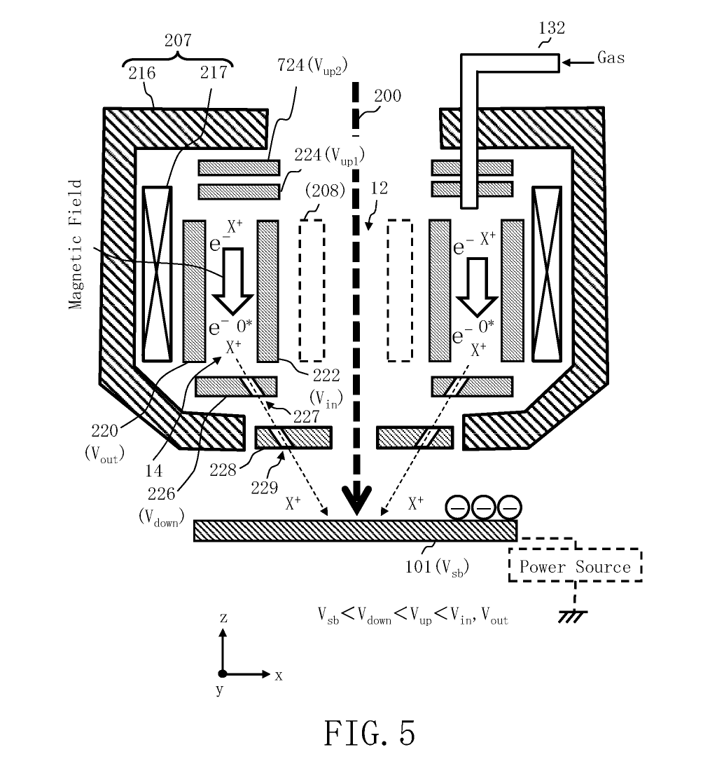

FIG. 5 is a sectional view showing another example of the configuration near the objective lens in Embodiment 1. FIG. 5 shows a modification of the configuration in FIG. 4.

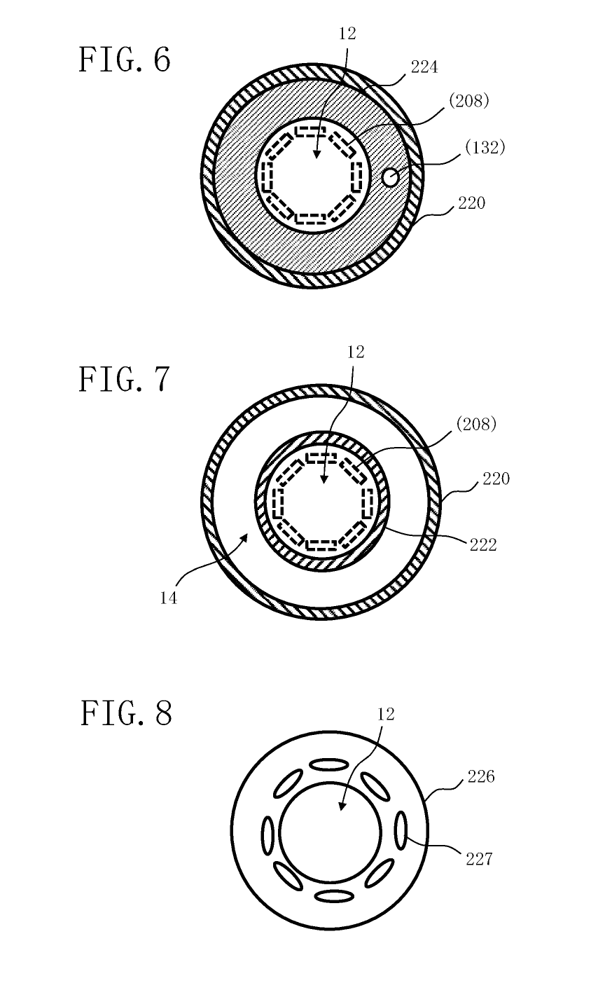

FIG. 6 is a top view when a state in which a plurality of electrodes according to Embodiment 1 is arranged is viewed from above the upper electrode.

FIG. 7 is a top view when the state in which the plurality of electrodes according to Embodiment 1 is arranged is viewed from an intermediate height position of the outer electrode.

FIG. 8 is a top view of the lower electrode of the plurality of electrodes according to Embodiment 1. As shown in FIGS. 4 to 7, the outer electrode 220 is formed in a cylindrical shape and is arranged so as to surround the outer circumferential surface of the inner electrode 222 formed similarly in a cylindrical shape. The height dimension of the outer electrode 220 and the inner electrode 222 is formed with a size that can be arranged in the space between the upper surface portion and the lower surface portion of the pole piece 216. The upper electrode 224 is formed like a disk in which an opening is formed for passing the electron beam 200 at a central portion and arranged above the outer electrode 220 and the inner electrode 222 so as to cover an upper portion of the space 14 sandwiched between the outer electrode 220 and the inner electrode 222. The lower electrode 226 is formed like a disk in which an opening is formed for passing the electron beam 200 at a central portion and arranged below the outer electrode 220 and the inner electrode 222 so as to cover a lower portion of the space 14 sandwiched between the outer electrode 220 and the inner electrode 222. The outer electrode 220 and the inner electrode 222 are arranged in a space between the upper surface portion and the lower surface portion of the pole piece 216. Alternatively, at least the outer electrode 220 is arranged in a space between the upper surface portion and the lower surface portion of the pole piece 216, and the inner electrode 222 is arranged on the inner side (optical axis side) than the pole piece 216 and also on the outer side of the passing region 12 of the electron beam 200. In the example of FIG. 4, the inner electrode 222 is arranged on the outer side of the deflector 208. The upper electrode 224 and the lower electrode 226 are also arranged in the space between the upper surface portion and the lower surface portion of the pole piece 216. Further, the gas supply line 132 is connected to or penetrates the upper electrode 224. In addition, a plurality of openings 227 through which ions and/or active species are allowed to pass is formed in the lower electrode 226. In FIG. 4, the deflector 208 not involved in plasma generation is indicated by a dotted line. As a material of the electrodes 220, 222, 224, 226, 228, a material with less sputtering due to ion bombardment, for example, glassy carbon can be used.

Since each electrode is exposured to high-temperature plasma, the heat inflow from the plasma may become large depending on the conditions of plasma. Therefore, a cooling means is provided if necessary. For example, water-cooled piping may be attached to the outside of the electrode so that cooling water is circulated using a constant-temperature water circulation device via a pipe made of an insulator. This also applies to other Embodiments.

The potential control circuit 124 (potential control unit) according to Embodiment 1 controls the potentials of a plurality of electrodes such as the outer electrode 220, the inner electrode 222, the upper electrode 224, and the lower electrode 226 so as to generate plasma in the space 14 surrounded by the plurality of electrodes and so as to control the movement of positive ions, or electrons and negative ions generated by the plasma. A more specific operation is as described below. Plasma is generated in the space 14 in a vacuum state surrounded by the plurality of electrodes such as the outer electrode 220, the inner electrode 222, the upper electrode 224, and the lower electrode 226 using the plurality of electrodes such as the outer electrode 220, the inner electrode 222, the upper electrode 224, and the lower electrode 226 and a magnetic field space of the objective lens 207. The plasma is generated by, for example, the Penning discharge. Here, the Penning discharge is a discharge that, by providing a space including a region of low potential on both ends of a region of high potential along lines of magnetic force, traps electrons in the region of high potential, thereby generating or maintaining a discharge of a gas in the space. A potential Vout is applied to the outer electrode 220 and a potential Vin is applied to the inner electrode 222 from the potential control circuit 124 while allowing a predetermined gas to flow from the gas supply line 132 in a state where a strong longitudinal magnetic field is generated by the objective lens 207 in the space 14 surrounded by the outer electrode 220, the inner electrode 222, the upper electrode 224, and the lower electrode 226.

In this case, the same potential is applied as the potential Vout of the outer electrode 220 and the potential Vin of the inner electrode 222. When the potential Vout of the outer electrode 220 and the potential Vin of the inner electrode 222 become higher than the potentials of the upper electrode 224 and the lower electrode 226 by a predetermined potential difference or more, plasma by the Penning discharge can be generated in the space 14. It is effective to reduce the amount of supply gas necessary to maintain discharge by closing gap portions of the four electrodes 220, 222, 224, 226 with an insulator such as ceramic so as to provide airtightness to suppress the outflow of the supplied gas from the space 14. Also, the load of an exhaust system required for maintaining the vacuum in a region through which the electron beam passes can be reduced. Further, for example, a vacuum evacuation pipe may be connected to a position different in phase from the gas supply line 132 of the upper electrode 224 from outside so that evacuation of the space 14 can be performed.

It is effective in improving controllability of the pressure in the space 14 to make the evacuation speed of the vacuum evacuation pipe changeable. In order to efficiently start the discharge, a material that emits thermoelectrons by a tungsten filament or the like being heated may be installed near the upper electrode 224 so that the discharge is started by passing a current from an external power source for heating to emit electrons. Even if the filament current is stopped after the discharge starts normally, the discharge continues. As a method for assisting the discharge start, a high-frequency wave generated by a high frequency source placed outside the electron optical column is guided to the boundary of the space 14 by using a coaxial waveguide to be able to generate plasma by discharging the high-frequency wave into the space 14 using an antenna provided at the waveguide outlet, for example, a loop antenna or a horn antenna. The frequency of the microwave is set to, for example, an electron cyclotron frequency corresponding to the magnetic flux density near the center of the space 14 and plasma is generated by accelerating electrons by the electron cyclotron resonance phenomenon to promote the ionization phenomenon. The electron cyclotron frequency corresponding to the magnetic flux density 1T is about 28 GHz. In addition, introducing the high-frequency wave continuously is effective in maintaining the discharge. The electrons (e⁻) in the space 14 are restricted in movement in the radial direction by a strong longitudinal magnetic field. Further, electrons in the space 14 are also restricted in movement in the vertical direction by applying a potential Vup lower than the potential Vout and the potential Vin to the upper electrode 224 and also applying a potential Vdown lower than the potential Vout and the potential Vin to the lower electrode 226. For example, a magnetic field of 4 to 6 kG is generated by the objective lens 207. In such a magnetic field space, the potential difference between Vin, Vout and Vup, Vdown is set such that Vin, Vout are higher by, for example, about 1 kV. For example, 50 V is applied as the potential Vout. As the potential Vin, for example, 50 V, which is the same potential as the potential Vout, is applied. For example, −850 V is applied as the potential Vup. For example, −950 V is applied as the potential Vdown. The retarding electrode 228 is grounded. Due to this effect, trapped electrons ionize the gas molecules supplied from the gas supply line 132 to generate ions (for example, positive ions X⁺). At the same time, neutral active species (O*) such as radicals are generated. X⁺ is decelerated by an electric field between the lower electrode 226 and the retarding electrode 228 to become low-energy ions mainly of about 50 eV or less before reaching the surface of the target object. Ions of higher energy can be emitted on average by increasing the energy level of Vin, Vout, Vup, Vdown as a whole.

Incidentally, a grid structure may be adopted for the upper electrode 224 instead of a plate-like material so that, as shown in a modification of FIG. 5, a structure provided with an external upper electrode 724 to which a potential approximately the same as or higher than Vin, for example, 100 V, is applied further upstream can be created. In this case, some of the positive ions X⁺ accelerated toward the upper electrode 224 in the space 14 passes through the opening of the upper electrode 224 and then, the orbit thereof is reversed by an electric field between the upper electrode 224 and the external upper electrode 724 to return into the space 14. This is effective in increasing the confinement efficiency of the positive ions X⁺ in the space 14 and increasing the ion density in the space 14.

Further, a filament made of a refractory metal, for example, tungsten may be installed near the opening 227 of the retarding electrode 228 so that electrons can be caused to reach the surface of the target object together with ions by supplying a current from an external power source (not shown) to heat the filament to emit electrons. In this manner, positive ions and electrons of low energy can reach the surface of the substrate 101. When the substrate surface is negatively charged, positive ions are absorbed by the substrate 101 and when positively charged, electrons are absorbed. Accordingly, electrification of the surface of the substrate 101 can be alleviated.

In Embodiment 1, as described above, ions (for example, positive ions X⁺), electrons (e⁻), and active species (O*) can be generated in the space 14 surrounded by a plurality of electrodes such as the outer electrode 220, the inner electrode 222, the upper electrode 224, and the lower electrode 226 by arranging the plurality of electrodes in the magnetic field space of the objective lens 207 and applying respectively set potentials. The electrification reduction (or removal) of the substrate 101 and/or the cleaning of contaminants (contamination removal) is performed using such ions (for example, positive ions X⁺), electrons (e⁻), and active species (O*). A gas that is not particularly ionized is sufficient as the gas supplied from the gas supply line 132. For example, an oxygen gas, a hydrogen gas, or a rare gas such as helium or argon is suitably used. Alternatively, water vapor may also be used.

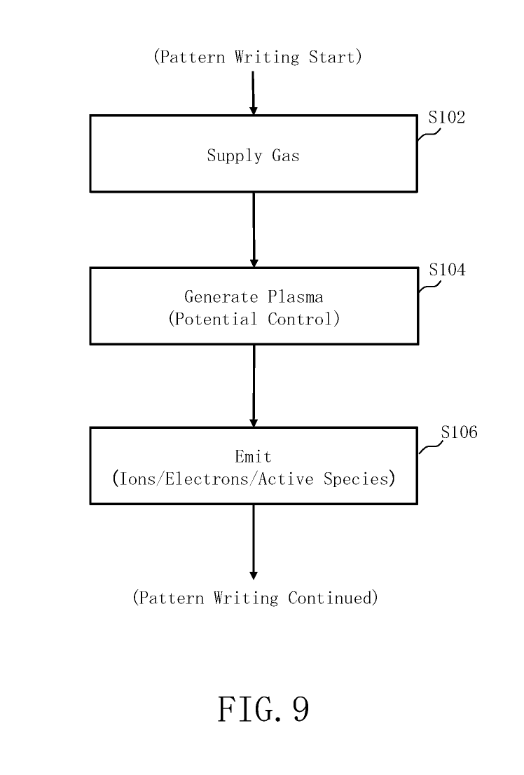

FIG. 9 is a flow chart showing principal processes of a method for reducing electrification according to Embodiment 1. In FIG. 9, the method for reducing electrification in Embodiment 1 performs a series of steps including a gas supply process (S102), a plasma generation process (S104), and an emission process (S106). A similar series of processes is also performed for the cleaning method in Embodiment 1. In FIG. 9, such a series of processes is performed after the start of pattern writing, but Embodiment 1 is not limited to such a case. Such a series of processes may be performed before the start of pattern writing or after the end of pattern writing. Alternatively, such a series of processes may be performed in a state in which pattern write processing is once stopped in the course of the pattern write processing, or in a period during which the pattern write processing is stopped while moving between pattern writing regions. In addition, it is also possible to continuously perform the gas supply and plasma generation so as to control the emission amount of ions/electrons.

As the gas supply process (S102), the gas supply device 130 supplies a gas into the electromagnetic lens (for example, the objective lens 207) through the gas supply line 132 under the control of the gas control circuit 126. Incidentally, as will be described below, the gas supply device 130 (supply mechanism) supplies a gas to the plasma space.

As the plasma generation process (S104), the potential control circuit 124 controls the potentials of a plurality of electrodes such as the outer electrode 220, the inner electrode 222, the upper electrode 224, and the lower electrode 226 arranged in a magnetic field space of the objective lens 207 that focuses the electron beam 200 on the surface of the substrate 101 and arranged so as to surround the space 14 on the outer side of the passing region 12 of the electron beam 200 to cause the plurality of electrodes to generate plasma in the space 14 surrounded by the plurality of electrodes and also to control the movement of positive ions, or electrons and negative ions generated by the plasma. More specifically, the potential control circuit 124 applies the potential Vout to the outer electrode 220 and the potential Vin, which is the same potential as the potential Vout, to the inner electrode 222. Then, a potential Vup lower than the potential Vout and the potential Vin is applied to the upper electrode 224 and a potential Vdown lower than the potential Vup is applied to the lower electrode 226. By applying such potentials, plasma by the Penning discharge can be generated in the space 14. At the same time, the vertical movement of electrons in the space 14 is also restricted.

However, due to the influence of the electric field and the magnetic field between the electrodes 224, 226 and the electrodes 220, 222, the gyrating center of electrons moves in the circumferential direction while the electrons are gyrating by the magnetic field. This is called an E×B (E cross B) drift. For the E×B drift, there is also an electric field arising from the charge distribution in plasma 14. Also, when the lines of magnetic field has a curvature, the gyrating center moves in the circumferential direction. Since the curvature of a magnetic field line is accompanied with a gradient of the amplitude of the magnetic flux density, and the latter also causes a drift, respective contributions are called a curvature drift and a gradient B drift.

As the emission process (S106), positive ions, electrons and negative ions, or active species are released from the space 14 of plasma. In the example of FIG. 4, the opening 227 is formed in the lower electrode 226 and also an opening 229 is formed in the retarding electrode 228 so as to form a passage from the space 14 surrounded by the plurality of electrodes to the irradiation position of the electron beam 200 of the substrate 101. The gas supply device 130 (supply mechanism) supplies a gas to the space 14 of plasma. In the space 14, the gas supplied through the gas supply line 132 is ionized, so that ions (positive ions X⁺), electrons (e⁻), and active species (O*) increase.) Therefore, when the potentials Vin, Vout, Vdown are higher than the potential of the substrate 101, mainly positive ions and active species (O*) are emitted from inside the space 14 using the openings 227, 229 as a flow channel. In particular, when the substrate 101 is negatively charged (a potential Vsb of the substrate 101 is a negative potential), the potential Vsb on the surface of the substrate 101 becomes lower than the potential Vdown and thus, more positive ions (X⁺) are released according to the potential difference from the space 14 of plasma toward the substrate 101. Then, the electrification of the substrate 101 is reduced by positive ions reaching the surface of the substrate 101.

Alternatively, positive ions (X⁺) may be emitted from the space 14 toward the substrate 101 by daring to apply the negative potential Vsb to the substrate 101 from a power source indicated by a dotted line in FIG. 4. Ion energy can be variably controlled by daring to apply a negative potential to the substrate 101. Ion energy can also be controlled by changing the potentials of a plurality of electrodes such as the outer electrode 220, the inner electrode 222, the upper electrode 224, and the lower electrode 226 by a constant value.

When a strong lens magnetic field is applied to the vicinity of the substrate 101 (a space from an opening (229 in this example) for emitting ions or electrons to a desired region of the substrate 101), the trajectory of positive ions is bent. Thus, by making the distance from the ion extraction port (opening) 229 to the desired region on the substrate 101 shorter than the reachable distance of ions, the ions can be made to reach the desired region. In the case of a uniform magnetic field, the distance should be shorter than twice the Larmor radius of the ion. For example, the Larmor radius ((√(2·MV/e))/B) in a uniform magnetic field B=1 kG of a monovalent positive argon ion (mass M=40×1.67e⁻²⁷ kg) with energy eV=50 eV is about 6.5 cm and so, positive ions of argon can be made to reach the desired region by bringing the ion extraction port 229 closer to the desired region such that the distance therebetween is shorter than twice the Larmor radius. The potential applied to each electrode and the amount of supply gas are adjusted so that emitted ions reach the desired position of the substrate with desired energy as a desired current.

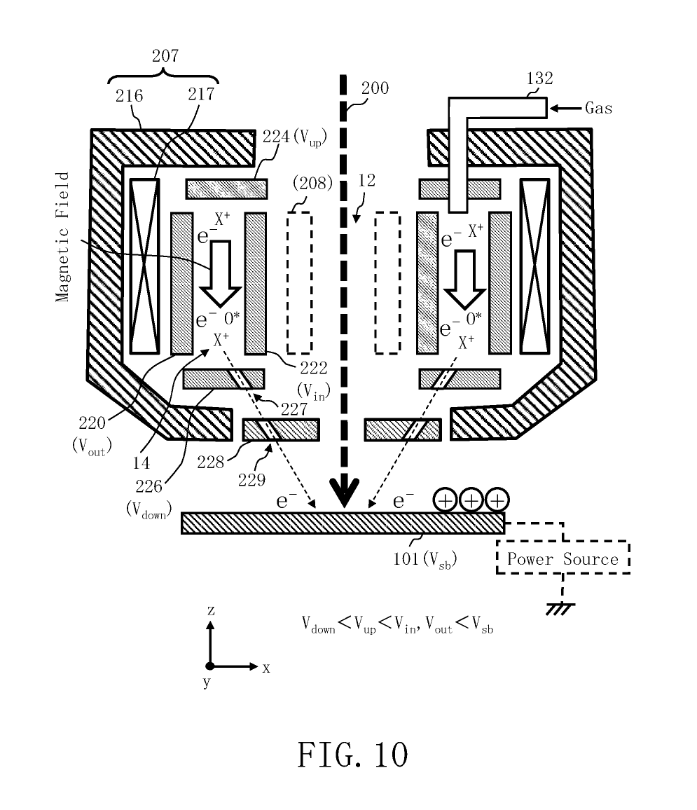

FIG. 10 is a sectional view showing still another example of the configuration near the objective lens in Embodiment 1. In FIG. 10, contents other than the fact that the surface of the substrate 101 is positively charged are the same as those in FIG. 4. However, the potentials of Vin, Vout, Vup, and Vdown are shifted to the negative side as a whole. For example, −10 V is applied as the potential Vout. As the potential Vin, for example, −50 V, which is the same potential as the potential Vout, is applied. For example, −950 V is applied as the potential Vup. As the potential Vdown, a potential lower than the potential Vup, for example, −1050 V is applied. In the example of FIG. 10, since ions (for example, positive ions X⁺, negative ions Y⁻), electrons (e⁻), and active species (O*) increase in the space 14 as described above, the negative ions Y⁻, electrons (e⁻), and active species (O*) are mainly emitted from inside the space 14 using the openings 227, 229 as a flow channel. The negative ions Y⁻ and electrons (e⁻) reaching the target object surface flow out without being returned by a decelerating electric field between Vin, Vout and Vdown, and the negative ions Y⁻ and electrons (e⁻) flowing out are mainly negative ions or electrons having high energy or those generated near the electrode 226. Low-energy positive ions are pulled back to the electrode 226 side by an electric field between the electrodes 226 and 228. In particular, when the substrate 101 is positively charged (the potential Vsb of the substrate 101 is a positive potential), more electrons (e⁻) and negative ions are emitted according to the potential difference from the space 14 of plasma toward the substrate 101. Then, the electrification of the substrate 101 is reduced by the electrons (e⁻) and negative ions reaching the surface of the substrate 101. Further, when the potential Vsb on the surface of the substrate 101 is higher than the potential Vout (potential Vin), electrons (e⁻) and negative ions can be emitted more markedly. In order to create such a state, a positive potential Vsb may dare to be applied to the substrate 101 from a power source indicated by a dotted line in FIG. 10. Here, since the mass of a negative ion is much larger than that of an electron, the current due to electrons is generally larger than the current due to negative ions.

When a strong lens magnetic field is applied to the vicinity of the substrate 101, the mass of an electron is light and thus, it is difficult for electrons to reach a desired region on the surface of the substrate 101 because the trajectory thereof is easily bent by the magnetic field. On the other hand, the mass of a negative ion is large and thus, it is possible for negative ions to reach a desired position. For example, taking the negative ion O₂⁻ of a monovalent oxygen molecule (mass M=2×16×1.67e−²⁷ kg) with energy eV=50 eV in a uniform magnetic field of B=1 kG as an example, the Larmor radius (√/(2·MV/e))/B) is about 6 cm and so, negative ions of oxygen can be made to reach the desired region by bringing the ion extraction port 229 closer to the desired region as compared with twice the Larmor radius. The potential applied to each electrode and the amount of supply gas are adjusted so that emitted ions reach the desired position of the substrate with desired energy as a desired current.

In Embodiment 1, as described above, positive ions or electrons (and negative ions) can be emitted in accordance with the sign of electrification even when the surface of the substrate 101 is charged positively or negatively so that the electrification can be reduced or eliminated. Thus, Embodiment 1 can be applied regardless of the charged state. In addition, the electrode 226 may have a grid structure with a high opening ratio so that the electric field between the electrodes 226 and 227 can be made to penetrate the inner side of the electrode 226. The configuration can efficiently extract electrons (e⁻) and negative ions generated near the electrode 226 and thus is useful in extracting particularly electrons (e⁻) and negative ions.

In addition, by switching the voltage applied to the electrodes while continuing the plasma generation, it is possible to switch the extraction of positive ions, and electrons and negative ions.

The energy distribution and types (positive ions, negative ions/electrons) of charged particles (ions, electrons) emitted to the surface of the target object can be controlled by exercising control so as to change the potentials while maintaining the potential difference of Vin, Vout, Vup, Vdown. Further, the energy distribution of emitted charged particles can be controlled by further providing one or a plurality of grid structure electrodes between the electrode 226 and the electrode 228 and controlling the potential distribution thereof.

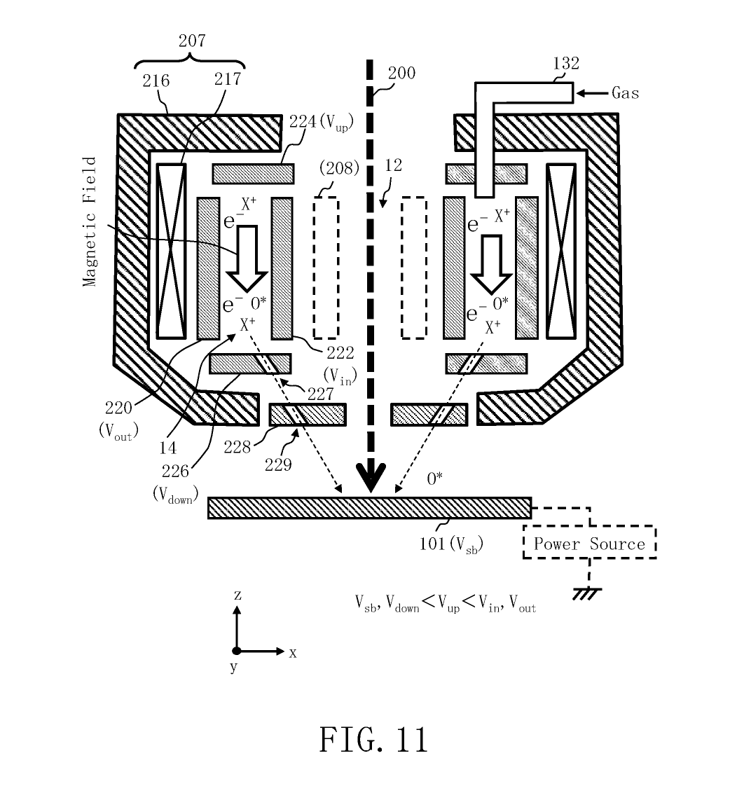

FIG. 11 is a sectional view showing still another example of the configuration near the objective lens in Embodiment 1. In FIG. 11, contents other than the fact that the surface of the substrate 101 is not specifically charged is the same as those in FIG. 4. Since ions (for example, positive ions X⁺), electrons (e⁻), and active species (O*) increase in the space 14 when the surface of the substrate 101 is not specifically charged, ions (for example, positive ions X⁺), electrons (e⁻), and active species (O*) are emitted from the space 14 using the opening 227 as a flow channel. Here, by maintaining the potential of the electrode 226 lower than that of the electrode 228, the passage of positive ions X⁺ through the opening 229 is suppressed. Accordingly, more active species (O*) affect the substrate 101. Therefore, impurities (contamination) adhering to the surface of the substrate 101 can be removed or reduced by the active species (O*).

Alternatively, by daring to apply a negative potential to the substrate 101 from a power source indicated by a dotted line in FIG. 11, control may be exercised so that the active species (O*) affect the substrate 101 more markedly by inhibiting electrons from reaching the substrate 101.

Also when the electrification reduction of the substrate 101 described above with reference to FIGS. 4 and 10 is performed, the active species (O*) are emitted to some degree and thus, even in such a case, the effect of removing impurities on the substrate 101 can somewhat be achieved at the same time.

In the above examples, the electrification reduction and/or impurity removal of the substrate 101 has been described, but Embodiment 1 is not limited to such examples.

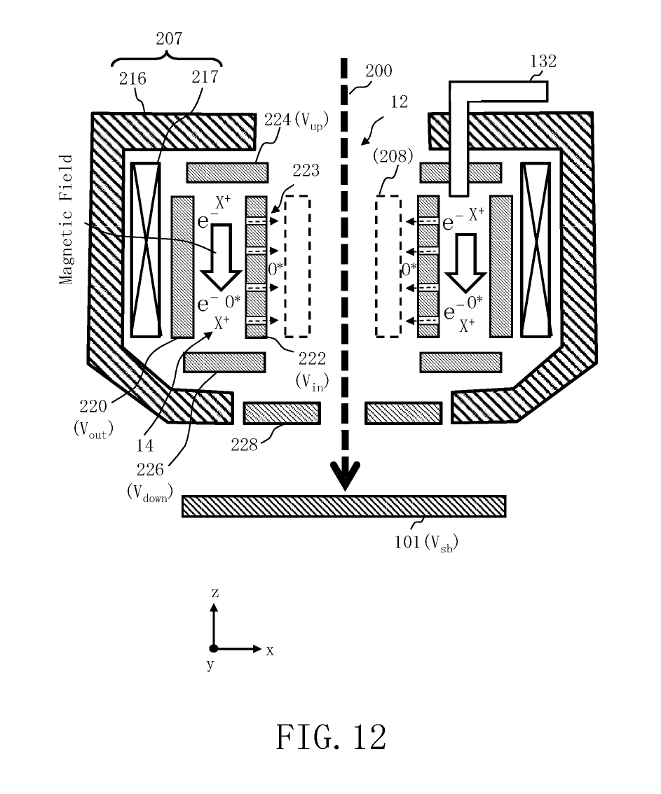

FIG. 12 is a sectional view showing still another example of the configuration near the objective lens in Embodiment 1. The potential distribution of each electrode is the same as in the example of FIG. 4. In FIG. 12, instead of the opening 227 of the lower electrode 226 and the opening 229 of the retarding electrode 228, a plurality of openings 223 is formed in the inner electrode 222 in the radial direction. Other configurations are the same as those in FIG. 4. In the example of FIG. 12, unlike the example of FIG. 4, no opening is formed in the lower electrode 226 and the retarding electrode 228 and thus, ions (for example, positive ions X⁺) and active species (O*) are less likely to be emitted to the substrate 101 side. Instead, ions (for example, positive ions X⁺) and active species (O*) are emitted from inside the space 14 to the deflector 208 side through the openings 223 of the inner electrode 222 as a flow channel. Since electrons are restricted in movement in the horizontal direction by the magnetic field, the emission of electrons is small. Thus, impurities (contamination) adhering to the surface of the deflector 208 can be removed or reduced by the active species (O*). As a result, the positional deviation of the deflection position of the electron beam 200 can be reduced or suppressed. Therefore, the positional deviation of the irradiation position of the electron beam 200 on the substrate 101 can be reduced or suppressed.

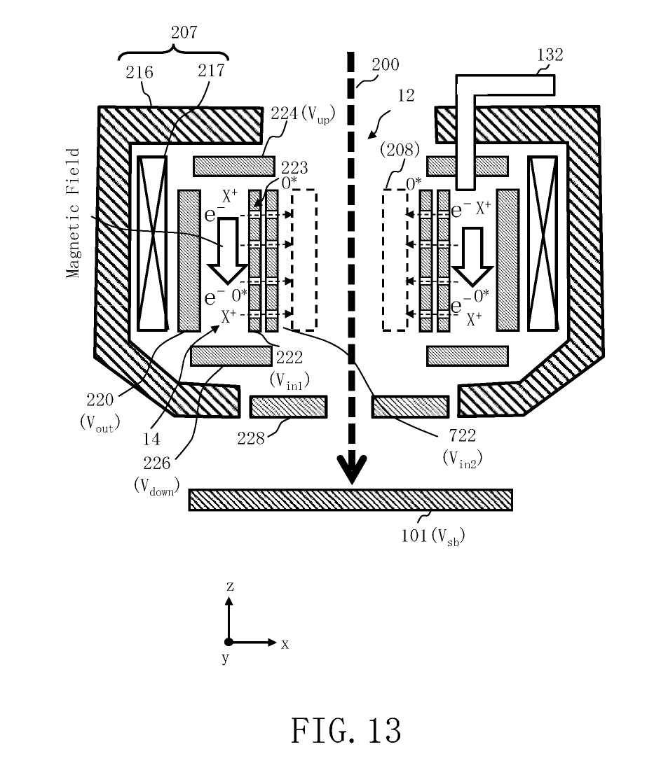

FIG. 13 is a sectional view showing still another example of the configuration near the objective lens in Embodiment 1. FIG. 13 shows a modification of FIG. 12.

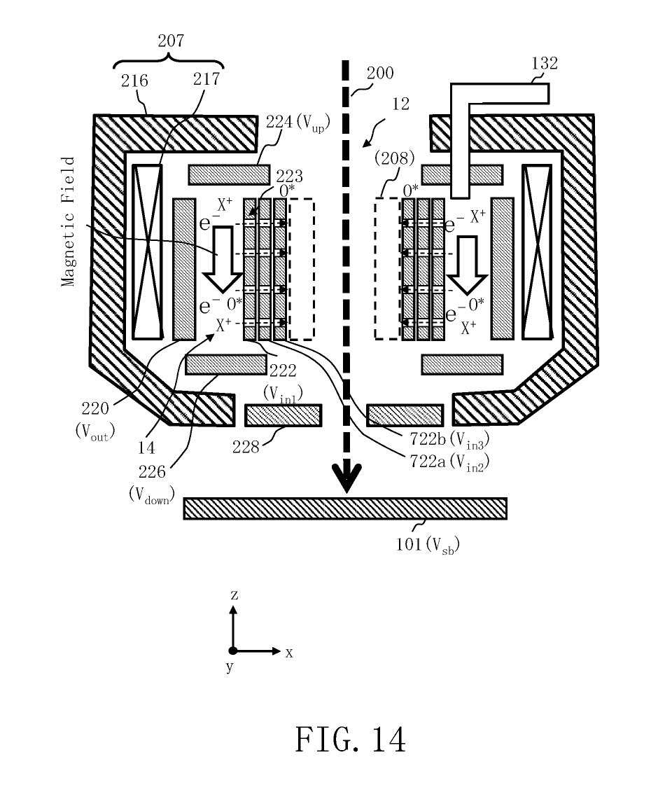

FIG. 14 is a sectional view showing still another example of the configuration near the objective lens in Embodiment 1. FIG. 14 shows a further modification of FIG. 12.

As shown in FIG. 13, it is also possible to adopt a double structure (222, 722) for the inner electrode and to apply a potential higher than Vin to the electrode 722 so as to suppress the outflow of positive ions X⁺ flowing out from the opening 223. Further, it is also possible to apply a potential lower than Vdown to the electrode 722 while retaining the same potential distribution of each electrode as the example in FIG. 11 so as to suppress the outflow of negative ions Y⁻ flowing out from the opening 223. As the electrode 722, a grid structure may be used or a plate material having an opening may be used. Further, as shown in FIG. 14, it is also possible to adopt a triple structure (222, 722a, 722b) for the inner electrode provided with both a grid for repelling positive ions and a grid for repelling electrons or negative ions.

In the example of FIG. 12, though the objective lens 207 is shown, by applying a similar configuration to the projection lens 204, the active species (O*) can be emitted to the deflector 205 for shaping. Thus, in such a case, impurities (contamination) adhering to the surface of the deflector 205 can be removed or reduced by the active species (O*). As a result, the positional deviation of the shaping deflection position of the electron beam 200 can be reduced or suppressed. Therefore, deviation of the beam size can be reduced or suppressed.

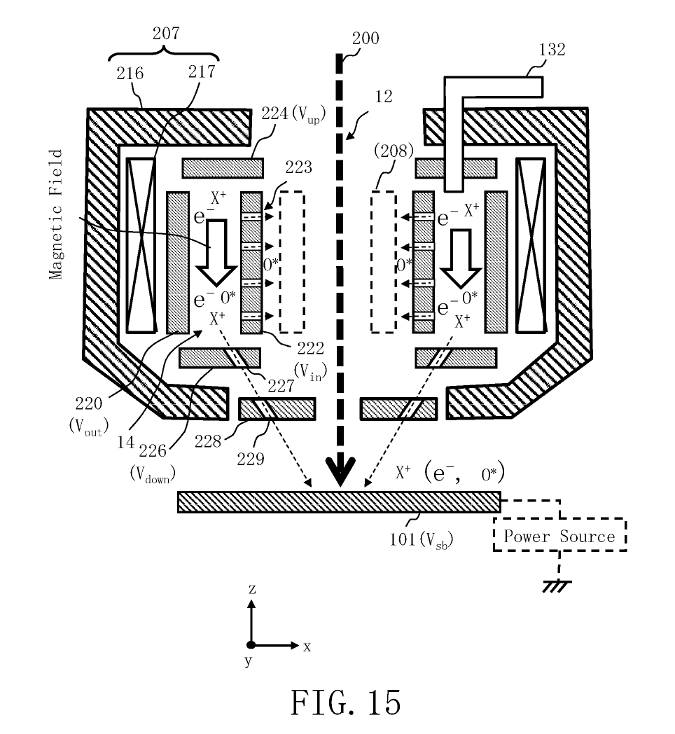

FIG. 15 is a sectional view showing still another example of the configuration near the objective lens in Embodiment 1. In FIG. 15, the plurality of openings 223 is formed in the inner electrode 222 in the radial direction. Other configurations are the same as those in FIG. 4. In the example of FIG. 15, similarly to the example of FIG. 4, the opening 227 of the lower electrode 226 and the opening 229 of the retarding electrode 228 are formed and then, the plurality of openings 223 is further formed in the inner electrode 222 in the radial direction. Thus, the emission of ions (for example, positive ions X⁺) and active species (O*) to the substrate 101 side and the emission of ions (for example, positive ions X⁺) and active species (O*) to the deflector 208 side can be carried out simultaneously. Therefore, it is possible to simultaneously perform electrification reduction or/and impurity removal of the substrate 101 and impurity removal from the deflector 208. Incidentally, the control of the potential Vsb of the substrate 101 may be appropriately adjusted, as described above, according to the charged state of the substrate 101.

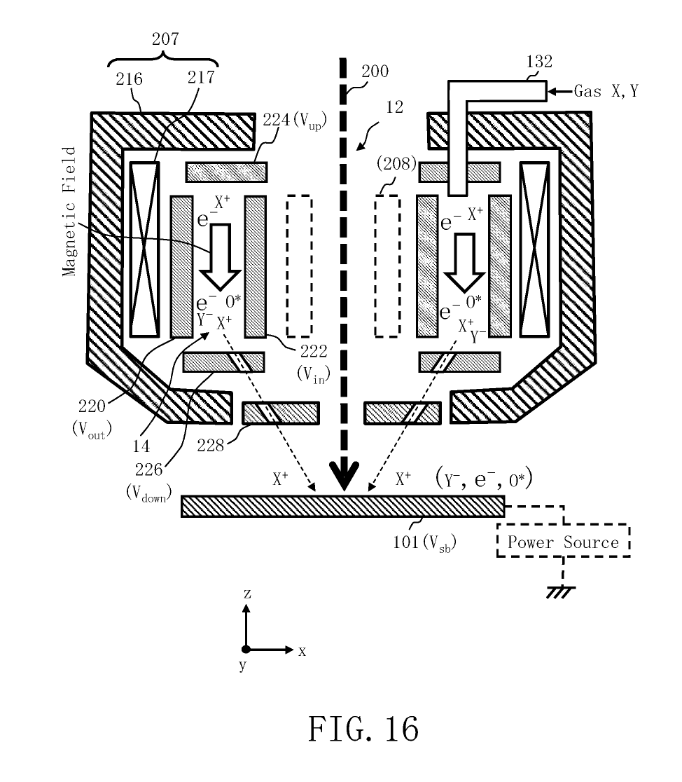

FIG. 16 is a sectional view showing still another example of the configuration near the objective lens in Embodiment 1. FIG. 16 is the same as FIG. 4 or FIG. 10 except that the gas supplied into the electromagnetic lens (for example, the objective lens 207) through the gas supply line 132 is a mixed gas or a compound gas of a plurality of types of gases. For example, when ionized by plasma, a case where a gas to be positive ions (X⁺) and a gas to be negative ions (Y⁻) are mixed and supplied corresponds. For example, a rare gas and an oxygen gas or water vapor are supplied. In the example of FIG. 16, positive ions (X⁺), negative ions (Y⁻), electrons (e⁻), and active species (O*) can be emitted by plasma to be generated.

In the above example, a case where the outer electrode 220 and the inner electrode 222 are used as a configuration in which plasma is to be generated in the magnetic field space on the outer side the passing region 12 of the electron beam 200 by Penning discharge has been described, but Embodiment 1 is not limited to such a case.

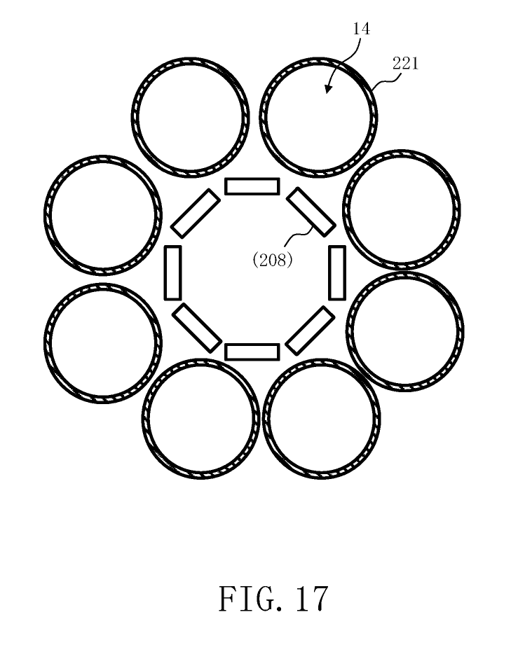

FIG. 17 is a top view when an example of the configuration near the objective lens according to a modification of Embodiment 1 is viewed from a height position between the upper electrode and the lower electrode. In FIG. 17, instead of the outer electrode 220 and the inner electrode 222 of FIG. 4 (FIG. 7), a plurality of ring electrodes 221 is arranged side by side in the circumferential direction in a magnetic field space on the inner side (on the optical axis side) of the coil 217 inside the pole piece 216 of the objective lens 207. More specifically, the plurality of ring electrodes 221 is arranged side by side in the circumferential direction in the space on the outer circumferential side of the deflector 208. The upper electrode 224 is arranged above the plurality of ring electrodes 221 arranged in the circumferential direction and the lower electrode 226 is arranged below the plurality of ring electrodes 221, which is the same as FIG. 4. Thus, the space inside each of the ring electrodes 221 is covered with the upper electrode 224 and the lower electrode 226. In the example of FIG. 17, a plurality of electrodes such as the plurality of ring electrodes 221, the upper electrode 224, and the lower electrode 226 is arranged so as to individually surround a plurality of spaces 14 obtained by dividing the space on the outer side of the passing region 12 of the electron beam 200.

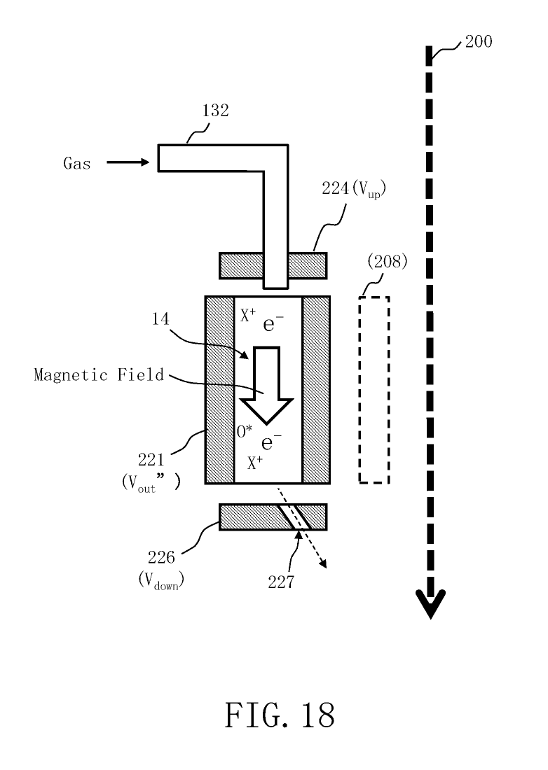

FIG. 18 is a diagram illustrating generation of plasma in the configuration near the objective lens in the modification of Embodiment 1. In FIG. 18, one of the plurality of ring electrodes 221 will be described. The same applies to the other ring electrodes 221. The potential control circuit 124 (potential control unit) generates plasma in the space 14 surrounded by a plurality of electrodes such as the plurality of ring electrodes 221, the upper electrode 224, and the lower electrode 226, and also controls the potentials of the plurality of electrodes so as to control the movement of positive ions, or electrons and negative ions generated by the plasma. A more specific operation is as described below. Plasma is generated in the space 14 in a vacuum state surrounded by the plurality of electrodes such as the plurality of ring electrodes 221, the upper electrode 224, and the lower electrode 226 using the plurality of electrodes such as the plurality of ring electrodes 221, the upper electrode 224, and the lower electrode 226 and a magnetic field space of the objective lens 207. In the example of FIG. 18, similarly to the case described above, plasma is generated by, for example Penning discharge. A potential Vout″ is applied from the potential control circuit 124 to the plurality of ring electrodes 221 while allowing a predetermined gas to flow from the gas supply line 132 in a state where a strong longitudinal magnetic field is generated by the objective lens 207 in the space 14 surrounded by a plurality of electrodes such as the plurality of ring electrodes 221, the upper electrode 224, and the lower electrode 226. When the potential Vout″ becomes higher than a predetermined potential, plasma by the Penning discharge can be generated in the space 14 inside each of the ring electrodes 221. Further, the fact that the potential Vup lower than the potential Vout″ is applied to the upper electrode 224 and the potential Vdown lower than the potential Vup is applied to the lower electrode 226 is the same as in the example of FIG. 4 and the like. The electrons (e⁻) in the space 14 are restricted in movement in the radial direction by a strong longitudinal magnetic field. In addition, by applying the potential Vup lower than the potential Vout″ to the upper electrode 224 and the potential Vdown lower than the potential Vup to the lower electrode 226, electrons in the space 14 are restricted in movement also in the vertical direction. Due to this effect, trapped electrons ionize the gas molecules supplied from the gas supply line 132 to generate ions (for example, positive ions X⁺). At the same time, neutral active species (O*) such as radicals are generated.

In the modification of Embodiment 1, as described above, ions (for example, positive ions X⁺), electrons (e⁻), and active species (O*) can be generated in the space 14 surrounded by a plurality of electrodes such as the plurality of ring electrodes 221 arranged in the circumferential direction, the upper electrode 224, and the lower electrode 226 by arranging the plurality of electrodes in a magnetic field space of the objective lens 207 and applying respectively set potentials. The electrification reduction (or removal) of the substrate 101 and/or the cleaning of contaminants (contamination removal) is performed using such ions (for example, positive ions X⁺), electrons (e⁻), and active species (O*). The way of reducing (or removing) the electrification of the substrate 101 or/and cleaning of contaminants (contamination removal) is the same as in the example of FIG. 4 and the like. Incidentally, if the openings are formed on the optical axis side of the plurality of ring electrodes 221, contaminants of the deflector 208 can be cleaned, which is the same as in the example of FIG. 12.

According to Embodiment 1, as described above, it is possible to reduce the electrification of the substrate 101 or/and to remove contaminants of the substrate 101 (deflectors 205, 208) and the like without affecting a magnetic field generated by an electromagnetic lens (for example, the projection lens 204 and the objective lens 207) constituting an electron beam optical system inherent to the apparatus that emits the electron beam 200. As a result, high-precision pattern writing can be performed.

### Embodiment 2

In Embodiment 1, a case where plasma is generated by the Penning discharge using the magnetic field of an electromagnetic lens has been described, but the method for generating the plasma is not limited to such a case. In Embodiment 2, a configuration for generating plasma by a different method will be described. The configuration of the lithography apparatus 100 according to Embodiment 2 is similar to that of FIG. 1. In addition, the flowchart showing principal processes of the method for reducing electrification in Embodiment 2 is similar to that of FIG. 9. The contents not specifically described below may be the same as those in Embodiment 1.

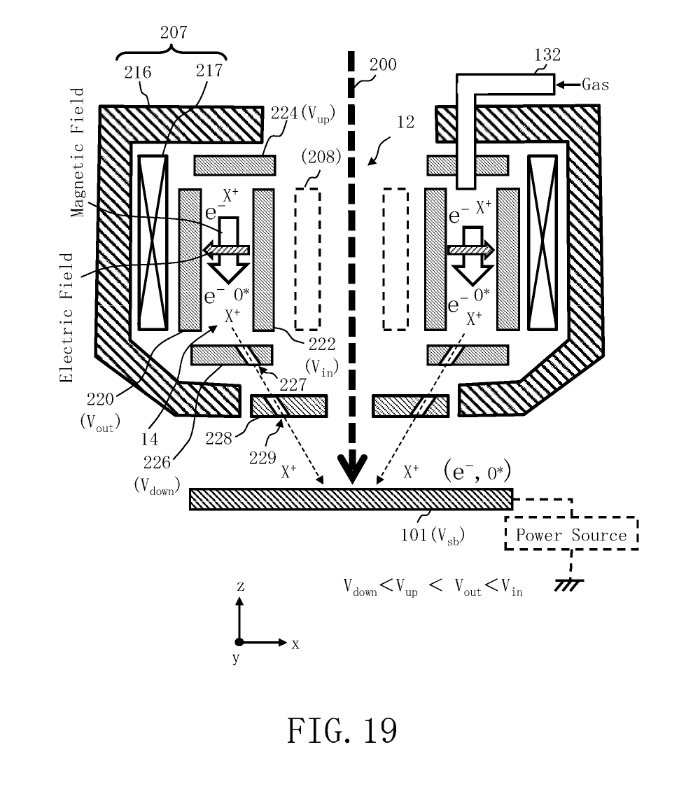

FIG. 19 is a sectional view showing an example of the configuration near the objective lens in Embodiment 2. FIG. 19 is the same as FIG. 4 except that an arrow indicating the direction of an electric field is added and electrons and active species are added in parenthesis as a gas emitted onto the substrate 101. The sectional configuration in FIG. 19 is similar to that in FIG. 4. A top view when a state in which a plurality of electrodes according to Embodiment 2 is arranged is viewed from above an upper electrode is similar to FIG. 6. A top view when the state in which the plurality of electrodes according to Embodiment 2 is arranged is viewed from an intermediate height position of an outer electrode is similar to FIG. 7. A top view of a lower electrode of the plurality of electrodes according to Embodiment 2 is similar to FIG. 8. Thus, the contents of the configuration itself near the objective lens are the same as those in Embodiment 1. However, in the example of FIG. 19, the way of applying the potential to each electrode is different. In Embodiment 2, plasma is generated by magnetron discharge. Here, the discharge that discharges a gas in a space in which an electric field almost perpendicular to lines of magnetic force is present is called the magnetron discharge. In order to efficiently start the discharge, a material that emits thermoelectrons by a tungsten filament or the like being heated may be installed near the upper electrode 224 so that the discharge is started by passing a current from an external power source for heating to emit electrons. Even if the filament current is stopped after the discharge starts normally, the discharge continues.

The potential control circuit 124 (potential control unit) according to Embodiment 2 controls the potentials of a plurality of electrodes such as the outer electrode 220, the inner electrode 222, the upper electrode 224, and the lower electrode 226 so as to generate plasma in the space 14 surrounded by the plurality of electrodes and so as to control the movement of positive ions, or electrons and negative ions generated by the plasma. A more specific operation is as described below. Plasma is generated in the space 14 in a vacuum state of a magnetic field space of the objective lens 207 and surrounded by a plurality of electrodes such as the outer electrode 220, the inner electrode 222, the upper electrode 224, and the lower electrode 226. The plasma is generated here by the magnetron discharge. A potential Vout is applied to the outer electrode 220 and a potential Vin is applied to the inner electrode 222 from the potential control circuit 124 while allowing a predetermined gas to flow from the gas supply line 132 in a state where a strong longitudinal magnetic field is generated by the objective lens 207 in the space 14 surrounded by the outer electrode 220, the inner electrode 222, the upper electrode 224, and the lower electrode 226. In such a case, a potential sufficiently lower than the potential Vin is applied as the potential Vout of the outer electrode 220. When the potential difference between the potential Vout of the outer electrode 220 and the potential Vin of the inner electrode 222 becomes larger than a predetermined potential difference, plasma by the magnetron discharge can be generated in the space 14. Further, a potential Vup lower than the potential Vout and the potential Vin is applied to the upper electrode 224 and also, a potential Vdown lower than the potential Vout and the potential Vin is applied to the lower electrode 226. For example, a magnetic field of 4 to 6 kG is generated by the objective lens 207. In such a magnetic field space, for example, 50 V is applied as the potential Vin. For example, −850 V is applied as the potential Vout. As the potential Vup, a potential lower than the potential Vout, for example, −1000 V is applied. As the potential Vdown, a potential lower than the potential Vup, for example, −1050 V is applied. Due to this effect, trapped electrons ionize the gas molecules supplied from the gas supply line 132 to generate ions (for example, positive ions X⁺). At the same time, neutral active species (O*) such as radicals are generated.

Like in Embodiment 1, a grid structure may be adopted for the upper electrode 224 instead of a plate-like material so that a structure provided with the external upper electrode 724 to which a potential approximately the same as or higher than Vin, for example, 100 V, is applied further upstream can be created.

In addition, the electrode 226 may have a grid structure with a high opening ratio so that the electric field between the electrodes 226 and 228 can be made to penetrate the inner side of the electrode 226. The configuration can efficiently extract electrons (e⁻) and negative ions generated near the electrode 226 and thus is useful in extracting particularly electrons (e⁻) and negative ions.

Here, the energy distribution and types (positive ions, negative ions/electrons) of charged particles (ions, electrons) emitted to the surface of the target object can be controlled by exercising control so as to change the potentials while maintaining the potential difference of Vin, Vout, Vup, Vdown. Further, the energy distribution of emitted charged particles can be controlled by further providing one or a plurality of grid structure electrodes between the electrode 226 and the electrode 228 and controlling the potential distribution thereof.

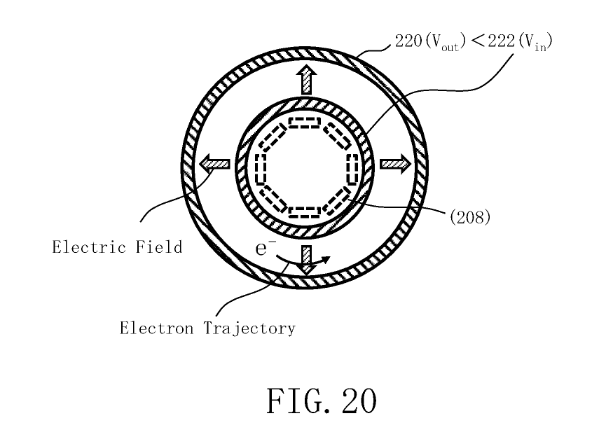

FIG. 20 is a diagram illustrating an electric field and a trajectory of a gyrating center of an electron in Embodiment 2. In FIG. 20, in Embodiment 2, since a potential difference arises between the potential Vout of the outer electrode 220 and the potential Vin of the inner electrode 222, an electric field from the outer electrode 220 toward the inner electrode 222 is generated. The electric field is formed in a direction orthogonal to the direction of the magnetic field by the objective lens 207. The strong longitudinal magnetic field by the objective lens 207 restricts the movement of electrons (e⁻) in the space 14 in the radial direction. In addition, by applying the potential Vup lower than the potential Vout and the potential Vin to the upper electrode 224 and the potential Vdown lower than the potential Vup to the lower electrode 226, the movement of electrons in the space 14 is restricted also in the vertical direction. This is similar to the Penning discharge. However, when the collision can be ignored, the gyrating center of electrons (e⁻) in the space 14 rotates in the circumferential direction in the space 14 in a ring shape between the outer electrode 220 and the inner electrode 222 due to the combination effect of the electric field and the magnetic field, in addition to the Larmor rotation in the magnetic field. This phenomenon is called the E×B drift. Thus, the plasma generated by the magnetron discharge can increase the uniformity in the space 14 in a ring shape between the outer electrode 220 and the inner electrode 222, as compared with the plasma generated by the Penning discharge. Incidentally, the E×B drift also occurs due to the electric field between the electrodes 220, 222 and the electrodes 224, 226. In addition, a curvature drift and a gradient B also occur when lines of magnetic force are bent. In the E×B drift, there is also an electric field contribution due to the bias of the charge distribution in the plasma.

In Embodiment 2, as described above, ions (for example, positive ions X⁺), electrons (e⁻), and active species (O*) can be generated by plasma by the magnetron discharge in the space 14 surrounded by a plurality of electrodes such as the outer electrode 220, the inner electrode 222, the upper electrode 224, and the lower electrode 226 by arranging the plurality of electrodes in the magnetic field space of the objective lens 207 and applying respectively set potentials. The charging reduction (or removal) of the substrate 101 or/and the cleaning of contaminants (contamination removal) is performed using such ions (for example, positive ions X⁺) and active species (O*). A gas that is not particularly ionized is sufficient as the gas supplied from the gas supply line 132. For example, an oxygen gas, a hydrogen gas, or a rare gas such as helium or argon is suitably used. Alternatively, water vapor may also be used. In Embodiment 2, by using the magnetron discharge, it is possible to reduce or eliminate an uneven distribution of occurrence locations of ions (for example, positive ions X⁺), electrons (e⁻), and active species (O*) in the space 14 in a ring shape. Therefore, the uniformity of emission amount when ions (for example, positive ions X⁺) and active species (O*) are emitted toward the substrate 101 can be enhanced.

Further, a filament made of a refractory metal, for example, tungsten may be installed near the opening 227 of the retarding electrode 228 so that electrons can be caused to reach the surface of the target object together with ions by supplying a current from an external power source (not shown) to heat the filament to emit electrons.

Then, as the emission process (S106), positive ions or active species are emitted from the space 14 of plasma. In the example of FIG. 19, similarly to FIG. 4, the opening 227 is formed in the lower electrode 226 so as to form a passage from the space 14 surrounded by a plurality of electrodes toward the irradiation position of the electron beam 200 of the substrate 101 and also, the opening 229 is formed in the retarding electrode 228. The gas supply device 130 (supply unit) supplies a gas to the space 14 of plasma. In the space 14, the gas supplied through the gas supply line 132 is ionized, so that ions (positive ions X⁺), electrons (e⁻), and active species (O*) increase. Thus, ions (for example, positive ions X⁺) and active species (O*) are emitted from inside the space 14 using the openings 227, 229 as a flow channel. In particular, when the substrate 101 is negatively charged (a potential Vsb of the substrate 101 is a negative potential), the potential Vsb on the surface of the substrate 101 becomes lower than the potential Vdown and thus, more positive ions (X⁺) are released according to the potential difference from the space 14 of plasma toward the substrate 101. Then, the electrification of the substrate 101 is reduced by positive ions reaching the surface of the substrate 101. When a strong lens magnetic field is applied to the vicinity of the substrate 101, the trajectory of positive ions is bent. Therefore, by making the distance from the ion outlet 229 to the desired region on the substrate 101 shorter than the reachable distance of ions, the ions can be made to reach the desired region. In the case of a uniform magnetic field, the distance should be shorter than twice the Larmor radius of the ion. For example, the Larmor radius ((√(2·MV/e))/B) in a uniform magnetic field B=1 kG of a monovalent positive argon ion (mass M=40×1.67e⁻²⁷ kg) with energy eV=50 eV is about 6.5 cm and so, positive ions of argon can be made to reach the desired region by bringing the ion extraction port 229 closer to the desired region, as compared with twice the Larmor radius.

Alternatively, positive ions (X⁺) may be emitted from the space 14 toward the substrate 101 by daring to apply the negative potential Vsb to the substrate 101 from a power source indicated by a dotted line in FIG. 19. The potentials of the plurality of electrodes such as the outer electrode 220, the inner electrode 222, the upper electrode 224, and the lower electrode 226 can be lowered (made variable). Accordingly, the ion energy can be variably controlled so as not to be too high.

Alternatively, similarly to the example in FIG. 10, particularly when the substrate 101 is charged positively (when the potential Vsb of the substrate 101 is a positive potential), more electrons (e⁻) and negative ions are desirably emitted according to the potential difference from the space 14 of plasma toward the substrate 101. Then, the electrification of the substrate 101 is reduced by the electrons (e⁻) and negative ions reaching the surface of the substrate 101. Further, when the potential Vsb on the surface of the substrate 101 is higher than the potential Vout (potential Vin), electrons (e⁻) and negative ions can be emitted more markedly. In order to create such a state, while maintaining the potential difference between Vout, Vin, Vup, and Vdown like in the previous example, the potential of Vin is adjusted to be equal to, for example, the ground potential to facilitate emission of electrons and negative ions. A gas easily converted into negative ions by the discharge of oxygen or the like is suitably introduced as a raw material gas. The positive potential Vsb may dare to be applied to the substrate 101 from the power source indicated by the dotted line in FIG. 10. When a strong lens magnetic field is applied to the vicinity of the substrate 101, the mass of an electron is light and thus, it is difficult for electrons to reach a desired region on the surface of the substrate 101 because the trajectory thereof is easily bent by the magnetic field. On the other hand, the mass of a negative ion is large and thus, it is possible for negative ions to reach a desired position. For example, taking the negative ion O₂ of a monovalent oxygen molecule (mass M=2×16×1.67e−²⁷ kg) with energy eV=50 eV in a uniform magnetic field of B=1 kG as an example, the Larmor radius ((√(2·MV/e))/B) is about 6 cm and so, negative ions of oxygen can be made to reach the desired region by bringing the ion extraction port 229 closer to the desired region as compared with twice the Larmor radius.

Also in this case, the inner electrode 222, the upper electrode 224, and the lower electrode 226 may have a double structure so that unnecessary outflow of charged particles can be suppressed.

In Embodiment 2, as described above, like in Embodiment 1, positive ions or electrons (and negative ions) can be emitted in accordance with the sign of electrification even when the surface of the substrate 101 is charged positively or negatively so that the electrification can be reduced or eliminated. Thus, Embodiment 2 can be applied regardless of the charged state.

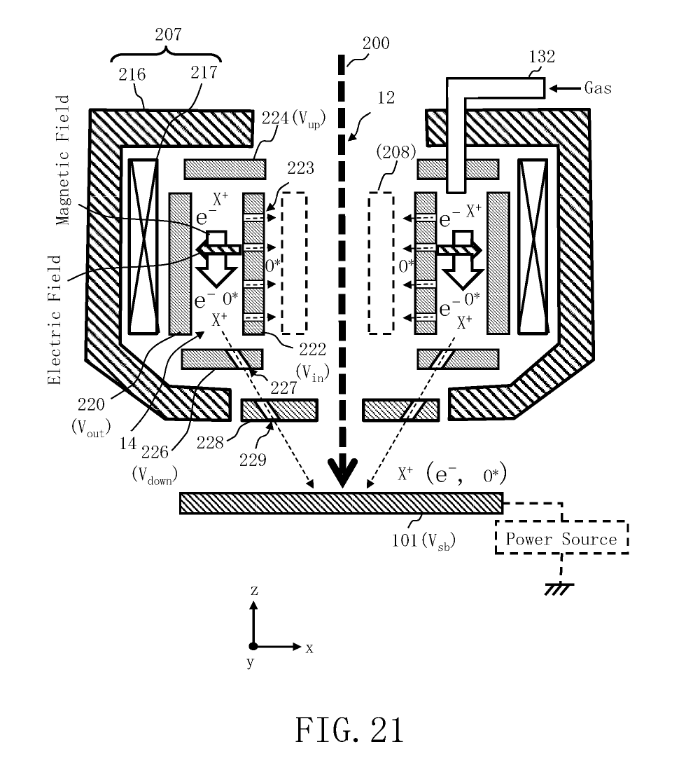

FIG. 21 is a sectional view showing another example of the configuration near the objective lens in Embodiment 2. In FIG. 21, a plurality of openings 223 is formed in the inner electrode 222 in the radial direction. Other configurations are the same as those in FIG. 19. In the example of FIG. 21, similarly to the example of FIG. 19, the opening 227 of the lower electrode 226 and the opening 229 of the retarding electrode 228 are formed and then, the plurality of openings 223 is further formed in the inner electrode 222 in the radial direction. Thus, the emission of ions (for example, positive ions X⁺), electrons (e⁻), and active species (O*) to the substrate 101 side and the emission of ions (for example, positive ions X⁺), electrons (e⁻), and active species (O*) to the deflector 208 side can be carried out simultaneously. Therefore, it is possible to simultaneously perform electrification reduction or/and impurity removal of the substrate 101 and impurity removal from the deflector 208. Incidentally, the control of the potentials of the electrodes 220, 222, 224, and 226 and the potential Vsb of the substrate 101 may be appropriately adjusted according to the charging state of the substrate 101 and the like as described above.

Also here, like in the example in Embodiment 1, it is possible to adopt a double structure (222, 722) for the inner electrode and to apply a potential higher than Vin by, for example, 50 V to an electrode 222a so as to suppress the outflow of positive ions X⁺ flowing out from the opening 223. Further, a potential lower than Vdown may be applied to the electrode 222a to suppress the outflow of negative ions Y⁻ flowing out from the opening 223. For the electrode 222a, a grid structure may be used, or a plate material having an opening may be used. Alternatively, by adopting a triple structure (222, 722a, 722b), it is also possible to have a structure that suppresses the outflow of both positive ions, and electrons or negative ions.

Like in Embodiment 1, it is needless to say that, instead of the opening 227 of the lower electrode 226 and the opening 229 of the retarding electrode 228, only the plurality of openings 223 may be formed in the inner electrode 222 in the radial direction. In such a case, impurities adhering to the deflector 208 due to the emission of active species (O*) to the deflector 208 side can be removed.

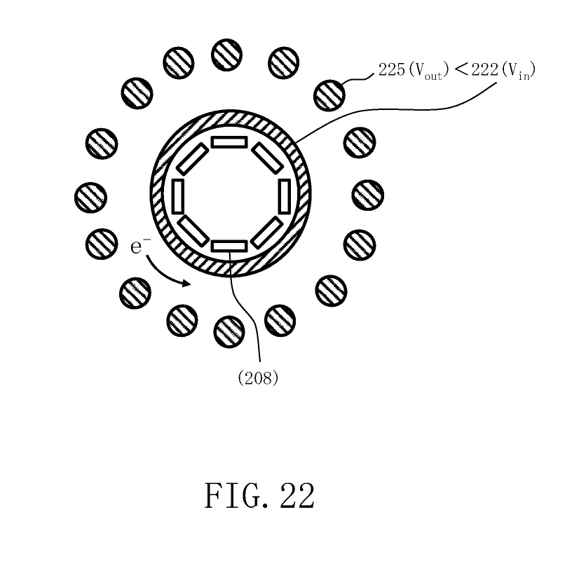

FIG. 22 is a top view when an example of the configuration near the objective lens according to a modification of Embodiment 2 is viewed from the height position between the upper electrode and the lower electrode. In FIG. 22, instead of the outer electrode 220 in FIG. 19, a plurality of cylindrical electrodes 225 is arranged side by side in the circumferential direction in a magnetic field space on the inner side (on the optical axis side) of the coil 217 inside the pole piece 216 of the objective lens 207. More specifically, the plurality of cylindrical electrodes 225 is arranged side by side in the circumferential direction in the space on the outer circumferential side of the inner electrode 222. The upper electrode 224 is arranged above the plurality of cylindrical electrodes 225 arranged in the circumferential direction and the lower electrode 226 is arranged below the plurality of cylindrical electrodes 225, which is the same as FIG. 19. In the example of FIG. 22, the plurality of electrodes such as the plurality of cylindrical electrodes 225, the inner electrode 222, the upper electrode 224, and the lower electrode 226 is arranged so as to surround the space 14 on the outer side of the passing region 12 of the electron beam 200.

The potential control circuit 124 (potential control unit) generates plasma in the space 14 surrounded by the plurality of electrodes such as the plurality of cylindrical electrodes 225, the inner electrode 222, the upper electrode 224, and the lower electrode 226, and also controls the potentials of the plurality of electrodes so as to control the movement of positive ions, or electrons and negative ions generated by the plasma. A more specific operation is as described below. Plasma is generated by the magnetron discharge in the space 14 in a vacuum state surrounded by the plurality of electrodes such as the plurality of cylindrical electrodes 225, the inner electrode 222, the upper electrode 224, and the lower electrode 226 using the plurality of electrodes such as the plurality of cylindrical electrodes 225, the inner electrode 222, the upper electrode 224, and the lower electrode 226 and a magnetic field space of the objective lens 207. The positive potential Vout is applied to the plurality of cylindrical electrodes 225 from the potential control circuit 124 while allowing a predetermined gas to flow from the gas supply line 132 in a state where a strong longitudinal magnetic field is generated by the objective lens 207. The potentials of the other electrodes are the same as those in FIG. 19. Accordingly, an electric field is generated from each of the cylindrical electrodes 225 toward the inner electrode 222. Therefore, like in FIG. 19, plasma by the magnetron discharge can be generated.

According to Embodiment 2, as described above, plasma by the magnetron discharge can be generated without affecting the magnetic field generated by the electromagnetic lens (for example, the projection lens 204 and the objective lens 207) constituting the electron beam optical system inherent to the apparatus that emits the electron beam 200. Therefore, it is possible to generate ions (for example positive ions X⁺), electrons (e⁻) and active species (O*), and also to reduce the electrification of the substrate 101 or/and to remove contaminants of the substrate 101 (deflectors 205, 208) and the like. As a result, high-precision pattern writing can be performed.

### Embodiment 3

In each of the above-described Embodiments, a case where a longitudinal magnetic field is generated by the objective lens 207 and plasma is generated by using such a longitudinal magnetic field has been described. However, the generation direction of the magnetic field is not limited to the above case. The configuration of the lithography apparatus 100 according to Embodiment 3 is the same as that in FIG. 1 except for the configuration of the objective lens described below and the configuration of a plurality of electrodes surrounding the plasma space. In addition, the flowchart showing principal processes of the method for reducing electrification in Embodiment 3 is similar to that of FIG. 9. The contents not specifically described below may be the same as those in Embodiment 1 or 2.

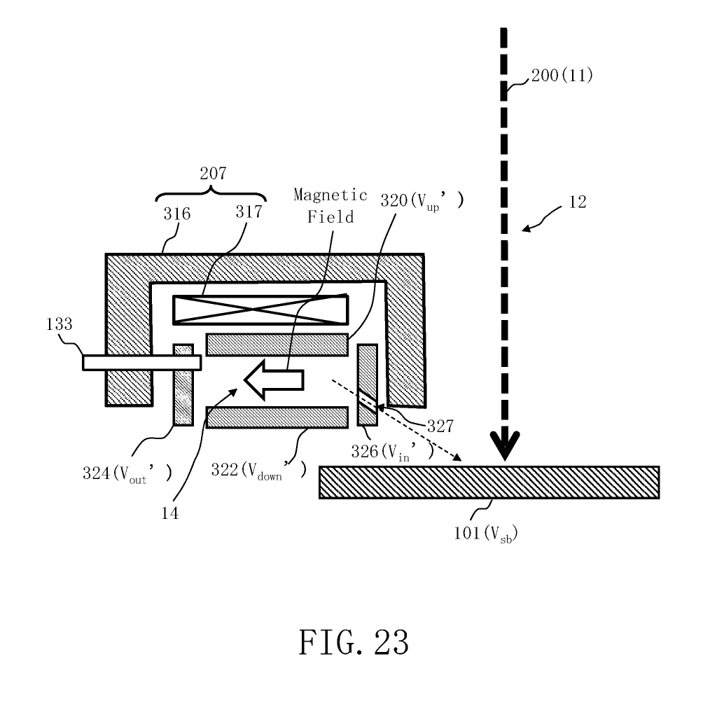

FIG. 23 is a sectional view showing an example of the configuration near the objective lens in Embodiment 3. The fact that each electromagnetic lens such as the illumination lens 202, the projection lens 204, and the objective lens 207 is constructed of a coil arranged so as to surround the optical axis of the electron beam 200 and a pole piece (yoke) surrounding the coil, and the fact that the pole piece (yoke) has an opening portion (also referred to as a gap) for leaking a high-density line of magnetic force generated by the coil to the optical axis side of the electron beam 200 formed therein are the same as described above. Here, as an example, the objective lens 207 will be described. In FIG. 23, the objective lens 207 has a pole piece (yoke) 316 and a coil 317. The pole piece 316 is formed in a horizontally long shape (long on the radial direction side orthogonal to the optical axis), and the coil 317 in a horizontally long shape is arranged inside. The central portion of the upper surface of the pole piece 316 is opened so as to secure a passing region of the electron beam and the lower surface thereof has an open shape (an opening portion is formed). The coil 317 is arranged at a position close to the upper side inside a space surrounded by the pole piece 316 in three directions of the upper surface and the outer and inner circumferential surfaces. In such a state, by passing a current toward the coil 317, the coil 317 generates lines of magnetic force in a direction orthogonal to the traveling direction of the electron beam 200 (toward the outer side in the radial direction in FIG. 23) in a space below the coil 317. In the example of FIG. 23, a cross section of the left-hand side of the optical axis 11 of the electron beam 200 is shown as an example. In such a cross section, the lines of magnetic force generated by the coil 317 turn clockwise inside the pole piece 316 itself. Then, a loop is formed by advancing lines of magnetic force from an inner circumferential side lower end of the pole piece 316 to an outer circumferential side lower end through a lower open space. Though an illustration is omitted, in a cross section on the right-hand side of the optical axis 11 of the electron beam 200, the lines of magnetic force generated by the coil 317 turn counterclockwise inside the pole piece 316 itself. Then, a loop is formed by advancing lines of magnetic force from an inner circumferential side lower end of the pole piece 316 to an outer circumferential side lower end through a lower open space. As described above, a magnetic field is generated in a direction orthogonal to the traveling direction of the electron beam 200 (outward in the radial direction in FIG. 23) in a space below (on the substrate side of) the coil 317. Therefore, in Embodiment 3, by generating plasma using a transverse magnetic field generated in the space below (on the substrate side of) the coil 317, a gas of ions or/and active species is generated.

In FIG. 23, a plurality of electrodes such as an upper electrode 320, a lower electrode 322, an outer electrode 324, and an inner electrode 326 is arranged in a magnetic field space below (on the substrate side of) the coil 317 inside the pole piece 316 of the objective lens 207. As shown in FIG. 23, the plurality of electrodes such as the upper electrode 320, the lower electrode 322, the outer electrode 324, and the inner electrode 326 is arranged so as to surround the space 14 on the outer side of the passing region 12 of the electron beam 200.

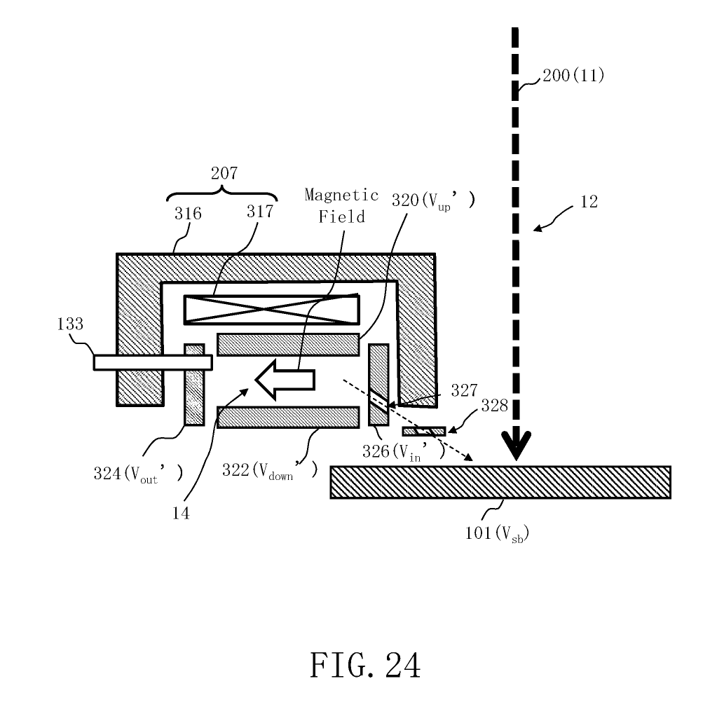

FIG. 24 is a sectional view showing another example of the configuration near the objective lens in Embodiment 3. FIG. 24 shows a modification of FIG. 23.

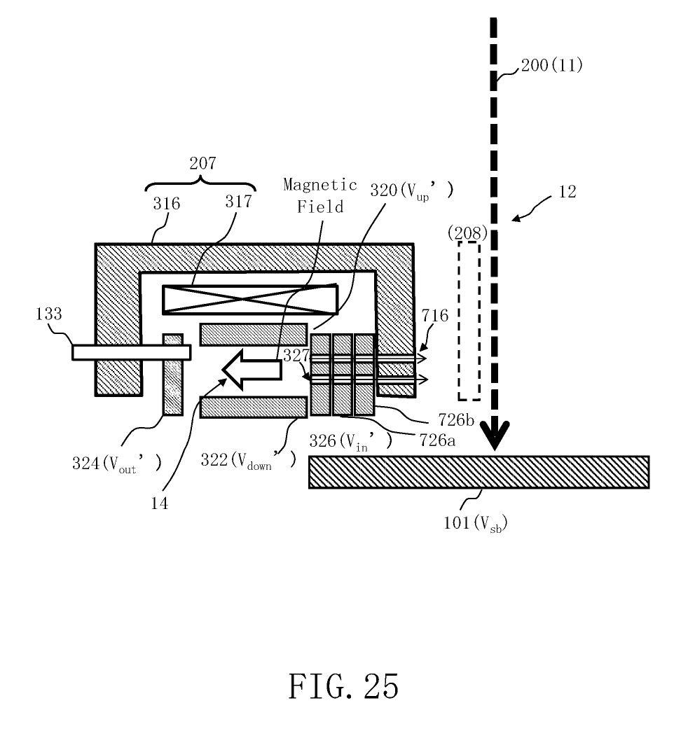

FIG. 25 is a sectional view showing still another example of the configuration near the objective lens in Embodiment 3. FIG. 25 shows a further modification of FIG. 23.

As shown in FIG. 24, a retarding electrode 328 may further be provided. Accordingly, an electric field generated on the trajectory of the electron beam 200 when potentials are applied to the electrodes 320, 322, 324, 326 can be shielded.

Further, as shown in FIG. 25, when the inner electrode 326 has a double structure (326, 726) or a triple structure (326, 726a, 726b), neutral active species may be introduced into the pole piece through the opening 716 provided in the inner wall of the pole piece 316 to use for cleaning the deflector 208 by applying a potential for repelling positive ions or a potential for repelling negative ions and electrons to 726 for the double structure or by repelling positive ions by 726a and negative ions and electrons by 726b for the triple structure.

The potential control circuit 124 (potential control unit) according to Embodiment 3 controls the potentials of a plurality of electrodes such as the upper electrode 320, the lower electrode 322, the outer electrode 324, and the inner electrode 326 so as to generate plasma in the space 14 surrounded by the plurality of electrodes and also so as to control the movement of positive ions, or electrons and negative ions generated by the plasma. A more specific operation is as described below. Plasma is generated in the space 14 in a vacuum state surrounded by the plurality of electrodes such as the upper electrode 320, the lower electrode 322, the outer electrode 324, and the inner electrode 326 using the plurality of electrodes such as the upper electrode 320, the lower electrode 322, the outer electrode 324, and the inner electrode 326 and a magnetic field space of the objective lens 207.

When the plasma is generated by, for example, the Penning discharge, the potential is applied as follows. A potential Vup′ is applied to the upper electrode 320 and a potential Vdown′ is applied to the lower electrode 322 from the potential control circuit 124 while allowing a predetermined gas to flow from the gas supply line 132 arranged so as to pass through the outer electrode 324 in a state where a strong transverse magnetic field is generated by the objective lens 207 in the space 14. In such a case, an equal positive potential is applied as the potential Vup′ of the upper electrode 320 and the potential Vdown′ of the lower electrode 322. When the potential Vup′ of the upper electrode 320 and the potential Vdown′ of the lower electrode 322 become higher than the potential Vout′ of the outer electrode 324 and the potential Vin′ of the inner electrode 326 by a predetermined potential difference or more, plasma by the Penning discharge can be generated in the space 14. The movement of electrons (e⁻) in the space 14 is restricted in the vertical direction by the strong transverse magnetic field. By applying a potential Vout′ lower than the potential Vup′ and the potential Vdown′ to the outer electrode 324 and a potential Vin′ lower than the potential Vout′ to the inner electrode 326, the movement of electrons in the space 14 is also restricted in the radial direction. For example, a magnetic field of 4 to 6 kG is generated by the objective lens 207. In such a magnetic field space, for example, 50 V is applied as the potential Vup′. As the potential Vdown′, for example, 50 V, which is the same potential as the potential Vup′, is applied. As the potential Vout′, a potential lower than Vdown′, for example, −850 V is applied. As the potential Vin′, a potential lower than the potential Vin′, for example, −950 V is applied. Due to this effect, trapped electrons ionize the gas molecules supplied from a gas supply line 133 to generate ions (for example, positive ions X⁺). At the same time, neutral active species (O*) such as radicals are generated. In order to efficiently start the discharge, a material that emits thermoelectrons by a tungsten filament or the like being heated may be installed near the outer electrode 324 so that the discharge is started by passing a current from an external power source for heating the material to emit electrons. Even if the filament current is stopped after the discharge starts normally, the discharge continues. Further, a filament made of a refractory metal, for example, tungsten may be installed near an opening 327 of the inner electrode 326 or an opening of the retarding electrode 328 so that electrons can be caused to reach the surface of the target object together with positive ions X⁺ by supplying a current from an external power source (not shown) for heating the filament to emit electrons.

When the plasma is generated by, for example, the magnetron discharge, a potential sufficiently higher than the potential Vup′ of the upper electrode 320 is applied as the potential Vdown′ of the lower electrode 322. For example, 50 V is applied as Vdown′ and, for example, −850 V, −1050 V, and −1000 V are applied as Vup′, Vin′, and Vout′ respectively. When the potential difference between the potential Vup′ of the upper electrode 320 and the potential Vdown′ of the lower electrode 322 becomes larger than a predetermined potential difference, plasma by the magnetron discharge can be generated in the space 14. Due to this effect, trapped electrons ionize the gas molecules supplied from a gas supply line 133 to generate ions (for example, positive ions X⁺). At the same time, neutral active species (O*) such as radicals are generated. In order to efficiently start the discharge, a material that emits thermoelectrons by a tungsten filament or the like being heated may be installed near the outer electrode 324 so that the discharge is started by passing a current from an external power source for heating the material to emit electrons. Even if the filament current is stopped after the discharge starts normally, the discharge continues. Further, a filament made of a refractory metal, for example, tungsten may be installed near the opening 327 of the inner electrode 326 or the opening of the retarding electrode 328 so that electrons can be caused to reach the surface of the target object together with positive ions X⁺ by supplying a current from an external power source (not shown) for heating the filament to emit electrons.

Then, as the emission process (S106), positive ions, electrons and negative ions, or active species are emitted from the space 14 of plasma. In the example of FIG. 23, the opening 327 is formed in the inner electrode 326 so as to form a passage from the space 14 surrounded by a plurality of electrodes toward the irradiation position of the electron beam 200 of the substrate 101. The gas supply device 130 (supply unit) supplies a gas to the space 14 of plasma. In the space 14, the gas supplied through the gas supply line 133 is ionized, so that ions (positive ions X⁺), electrons (e⁻), and active species (O*) increase. Thus, ions (positive ions X⁺), electrons (e⁻), and active species (O*) are emitted from inside the space 14 using the opening 327 as a flow channel. Particularly, when the substrate 101 is negatively charged (when the potential Vsb of the substrate 101 is a negative potential), a potential is applied to each electrode so that more positive ions (X⁺) are emitted. Then, the electrification of the substrate 101 is reduced by positive ions reaching the surface of the substrate 101. Conversely, when the substrate 101 is positively charged (the potential Vsb of the substrate 101 is a positive potential), a potential is applied to each electrode so that more electrons (e⁻) and negative ions are emitted from the space 14 of plasma toward the substrate 101. Then, the electrification of the substrate 101 is reduced by the electrons (e⁻) and negative ions reaching the surface of the substrate 101. Or/and the active species (O*) are emitted from the space 14 of plasma toward the substrate 101 and thus, impurities on the substrate 101 can be removed.

In Embodiment 3, since a strong magnetic field is generally applied to the vicinity of the substrate 101, it is difficult to cause electrons to reach a desired region of the substrate 101. When irradiated with positive ions (X⁺) and negative ions (Y⁻), the potential of each electrode is adjusted in consideration of the Larmor radius so that a desired current can reach a desired region of the substrate 101.

According to Embodiment 3, as described above, plasma by the Penning discharge or magnetron discharge can be generated without affecting the magnetic field generated by the electromagnetic lens (for example, the projection lens 204 and the objective lens 207) constituting the electron beam optical system inherent to the apparatus that emits the electron beam 200 even if the magnetic field is a transverse magnetic field in the radial direction. Therefore, it is possible to generate ions (for example positive ions X⁺), electrons (e⁻) and active species (O*), and also to reduce the electrification of the substrate 101 or/and to remove contaminants of the substrate 101 (deflectors 205, 208) and the like. As a result, high-precision pattern writing can be performed.

### Embodiment 4

In each of Embodiments described above, the case where the plasma generation mechanism is applied to the lithography apparatus 100 using a single beam has been described. However, the present disclosure is not limited to such a case. In Embodiment 4, a case where a plasma generation mechanism is applied to a lithography apparatus using multiple beams will be described.

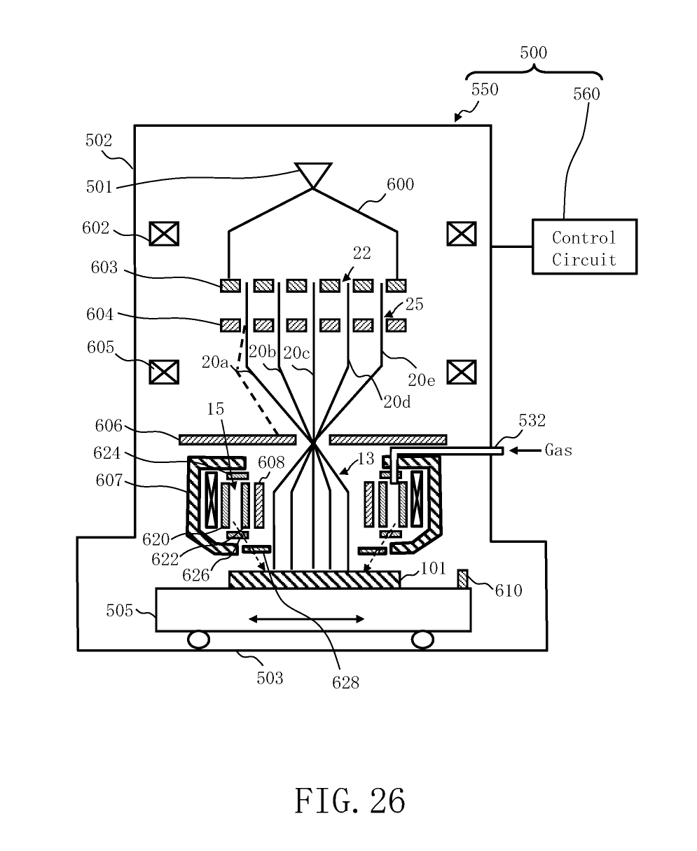

FIG. 26 is a conceptual diagram showing the configuration of a lithography apparatus according to Embodiment 4. In FIG. 26, a lithography apparatus 500 includes a pattern writing mechanism 550 and a control system circuit 560. The lithography apparatus 500 is an example of the multiple charged particle beam lithography apparatus. The pattern writing mechanism 550 includes an electron optical column 502 (multiple electron beam column) and a pattern writing chamber 503. Inside the electron optical column 502, an electron gun assembly 601, an illumination lens 602, a shaping aperture plate array substrate 603, a blanking aperture array mechanism 604, a reducing lens 605, a limiting aperture plate substrate 606, an objective lens 607, a deflector 608, electrodes 620, 622, 624, 626, a retarding electrode 628, and a gas supply line 532 are arranged. An XY stage 505 is arranged inside the pattern writing chamber 503. The target object 101 such as mask blanks to be a substrate intended for pattern writing while a pattern is written and to which a resist is applied is arranged on the XY stage 505. The target object 101 includes an exposure mask for manufacturing semiconductor devices or a semiconductor substrate (silicon wafer) on which semiconductor devices are manufactured. Further, a mirror 610 for position measurement of the XY stage 505 is arranged on the XY stage 505. The pattern writing mechanism 550 is controlled by the control system circuit 160.

Here, in FIG. 26, only the configuration needed to describe Embodiment 4 is shown. Other configurations normally needed for the lithography apparatus 500 may also be included. In addition, a flowchart showing principal processes of the method for reducing electrification in Embodiment 4 is similar to FIG. 9. The contents not specifically described below may be the same as those in one of Embodiments described above.

The shaping aperture plate array substrate 603 has holes (openings) 22 of p rows high (y direction)×q rows wide (x direction) (p, q≥2) formed with predetermined arrangement pitches in a matrix of rows and columns. For example, the holes 22 of 512×512 rows are formed in length and width (x, y directions). Each of the holes 22 is formed in a rectangular shape of the same size and shape. Alternatively, each of the holes 22 may be formed in a circular shape of the same diameter. With the passage of a portion of an electron beam 600 through the plurality of holes 22, multiple beams 20 are formed and also, each beam is formed into a desired shape. Also, the way of arranging the holes 22 is not limited to a case of arranging holes in a grid shape in length and width. For example, the holes in the k-th row and the (k+1)-th row in the length direction (y direction) may be arranged by being shifted by a dimension a in the width direction (x direction). Similarly, the holes in the (k+1)-th row and the (k+2)-th row in the length direction (y direction) may be arranged by being shifted by a dimension b in the width direction (x direction).

The shaping aperture plate array substrate 603 has a passing hole 25 (opening) for passing each beam of multiple beams opened at a position corresponding to each of the holes 22 formed in the shaping aperture plate array substrate 603. In other words, in a membrane region 330 of a substrate 31, a plurality of passing holes 25 through which corresponding beams of multiple beams using electron beams pass is formed in an array shape. Then, a plurality of electrode pairs having two electrodes is arranged at positions facing each other across the corresponding passing hole 25 of the plurality of passing holes 25. More specifically, a pair of a blanking deflecting control electrode and a counter electrode (blanker: blanking deflector) is arranged with the passing hole 25 therebetween.

The electron beam 20 passing through each passing hole is independently deflected by the voltages applied to the control electrode and the counter electrode forming a pair. Blanking control is exercised by such deflection. More specifically, a pair of the control electrode and the counter electrode individually deflects by blanking corresponding beams of the multiple beams by the potentials switched by respective corresponding switching circuits. Thus, a plurality of blankers deflects by blanking, among multiple beams having passed through the plurality of holes 22 (openings) of the shaping aperture plate array substrate 603, respective corresponding beams.

Next, the operation of the pattern writing mechanism 550 in the lithography apparatus 500 will be described. The electron beam 600 emitted from the electron gun assembly 601 (emission source) illuminates the entire shaping aperture plate array substrate 603 almost vertically through the illumination lens 602. A plurality of rectangular holes (openings) are formed in the shaping aperture plate array substrate 603, and the electron beam 600 illuminates a region including all the plurality of holes. A plurality of electron beams (multiple beams) 20a to 20e in, for example, a rectangular shape is formed by each portion of the electron beam 600 with which the positions of the plurality of holes are irradiated being passed through each of the plurality of holes of the shaping aperture plate array substrate 603. The multiple beams 20a to 20e pass through the respective corresponding blankers (first deflector: individual blanking mechanism) of the blanking aperture array mechanism 604. Such blankers individually deflect (deflect by blanking) the passing electron beam 20.

The multiple beams 20a to 20e having passed through the blanking aperture array mechanism 604 are reduced by the reducing lens 605 before traveling toward a hole in the center formed in the limiting aperture plate substrate 606. Here, the electron beam 20a deflected by the blanker of the blanking aperture array mechanism 604 deviates from the position of the hole in the center of the limiting aperture plate substrate 606 and is shielded by the limiting aperture plate substrate 606. Meanwhile, the electron beams 20b to 20e that are not deflected by the blanker of the blanking aperture array mechanism 604 pass, as shown in FIG. 26, through the hole in the center of the limiting aperture plate substrate 606. The blanking control is exercised by ON/OFF of the individual blanking mechanism to control ON/OFF of a beam. In this manner, the limiting aperture plate substrate 606 shields each beam deflected so as to be in a beam OFF state by the individual blanking mechanism. Then, a beam for one shot is formed for each beam by a beam formed between beam ON and beam OFF and having passed through the limiting aperture plate substrate 606. The multiple beams 20 having passed through the limiting aperture plate substrate 606 are focused by the objective lens 607 to become a pattern image of a desired reduction ratio and each beam (the multiple beams 20 as a whole) having passed through the limiting aperture plate substrate 606 is deflected collectively in the same direction by the deflector 608 and emitted toward the irradiation position of each beam on the target object 101. The multiple beams 20 emitted at a time are ideally arranged with pitches obtained by multiplying the arrangement pitch of the plurality of holes 22 of the shaping aperture plate array substrate 603 by the above desired reduction ratio.

As for the objective lens 607, like in each of Embodiments described above, a plasma generation mechanism can be constructed by arranging a plurality of electrodes inside. The objective lens 607 has, like the objective lens 207 in each Embodiment described above, a pole piece (yoke) and a coil. Then, a magnetic field is generated in the traveling direction of the electron beam 200 (downward in FIG. 26) in the space on the inner side (optical axis side) of the coil. Thus, in Embodiment 4, plasma is generated by using a magnetic field generated in the space on the inner side (optical axis side) of the coil to generate a gas of ions or/and active species.

In FIG. 26, a plurality of electrodes such as the outer electrode 620, the inner electrode 622, the upper electrode 624, and the lower electrode 626 is arranged in a magnetic field space on the inner side (optical axis side) of the coil inside the pole piece of the objective lens 607. As shown in FIG. 26, the plurality of electrodes such as the outer electrode 620, the inner electrode 622, the upper electrode 624, and the lower electrode 626 is arranged so as to surround a space 15 on the outer side of the passing region 13 of the multiple beams 20.

Then, a potential control circuit (potential control unit) (not shown) controls the potentials of the plurality of electrodes such as the outer electrode 620, the inner electrode 622, the upper electrode 624, and the lower electrode 626 so as to generate plasma in the space 15 surrounded by the plurality of electrodes and also so as to control the movement of positive ions, or electrons and negative ions generated by the plasma. As mentioned above, plasma can be generated by the Penning discharge or magnetron discharge.

When the plasma is generated by, for example, the Penning discharge, the potential is applied as follows. The potential Vout is applied to the outer electrode 620 and the potential Vin is applied to the inner electrode 622 from the potential control circuit (not shown) while allowing a predetermined gas to flow from the gas supply line 532 in a state where a strong transverse magnetic field is generated by the objective lens 607 in the space 15. In such a case, the same positive potential is applied as the potential Vout of the outer electrode 620 and the potential Vin of the inner electrode 622. The potential Vup lower than the potential Vout and the potential Vin is applied to the upper electrode 624 and the potential Vdown lower than the potential Vup is applied to the lower electrode 626. When the potential Vout of the outer electrode 620 and the potential Vin of the inner electrode 622 become higher than the potentials of the upper electrode 624 and the lower electrode 626 by a predetermined potential difference or more, plasma by the Penning discharge can be generated in the space 15. The value of each potential may be the same as that in Embodiment 1. When the potential Vout of the outer electrode 620 and the potential Vin of the inner electrode 622 become higher than a predetermined potential, plasma by the Penning discharge can be generated in the space 15. The movement in the horizontal direction of electrons (e⁻) in the space 15 is restricted by a strong longitudinal magnetic field. In addition, electrons in the space 15 are also restricted in movement in the vertical direction by an electric field associated with the potential distribution in the space 15. Due to this effect, trapped electrons ionize the gas molecules supplied from the gas supply line 532 to generate ions (for example, positive ions X⁺). At the same time, neutral active species (O*) such as radicals are generated. In order to efficiently start the discharge, a material like a tungsten filament that emits thermoelectrons by being heated may be installed near the upper electrode 624 so that the discharge is started by passing a current from an external power source for heating the material to emit electrons. Even if the filament current is stopped after the discharge starts normally, the discharge continues. Further, a filament made of a refractory metal, for example, tungsten may be installed near the opening of the retarding electrode 628 so that electrons can be caused to reach the surface of the target object together with ions by supplying a current from an external power source (not shown) for heating the filament to emit electrons.

When the plasma is generated by, for example, the magnetron discharge, a potential sufficiently higher than the potential Vout of the outer electrode 620 is applied as the potential Vin of the inner electrode 622. The value of the potential Vin may be the same as that in Embodiment 2. When the difference between the potential Vin of the inner electrode 622 and the potential Vout of the outer electrode 620 becomes larger than a predetermined potential difference, plasma by the magnetron discharge can be generated in the space 15. Due to this effect, trapped electrons ionize the gas molecules supplied from the gas supply line 532 to generate ions (for example, positive ions X⁺). At the same time, neutral active species (O*) such as radicals are generated. In order to efficiently start the discharge, a material like a tungsten filament that emits thermoelectrons by being heated may be installed near the upper electrode 624 so that the discharge is started by passing a current from an external power source for heating the material to emit electrons. Even if the filament current is stopped after the discharge starts normally, the discharge continues. Further, a filament made of a refractory metal, for example, tungsten may be installed near the opening of the retarding electrode 628 so that electrons can be caused to reach the surface of the target object together with ions by supplying a current from an external power source (not shown) for heating the filament to emit electrons.

When a magnetic field is applied to the vicinity of the substrate 101, the potentials of the respective electrodes are adjusted similarly to the above-described embodiment so that ions (positive ions X⁺, negative ions Y⁻) can be caused to reach desired regions of the substrate 101.

Then, as the emission process (S106), positive ions, electrons and negative ions, or active species are emitted from the plasma space 15. In the example of FIG. 26, openings are formed in the lower electrode 626 and the retarding electrode 628 so as to form a passage from the space 15 surrounded by a plurality of electrodes toward the irradiation position of the multiple beams 20 of the substrate 101. Then, a gas is supplied from the gas supply line 532 into the space 15 of plasma. In the space 15, the gas supplied through the gas supply line 532 is ionized, so that ions (for example, positive ions X⁺), electrons (e⁻), and active species (O*) increase. Thus, ions (for example, positive ions X⁺), electrons (e⁻), and active species (O*) are emitted from inside the space 15 using such openings as a flow channel. Particularly, when the substrate 101 is negatively charged (the potential Vsb of the substrate 101 is a negative potential), a potential is applied to each electrode so that more positive ions (X⁺) are emitted according to the potential difference from the space 15 of plasma toward the substrate 101. Then, the electrification of the substrate 101 is reduced by positive ions reaching the surface of the substrate 101. Conversely, when the substrate 101 is positively charged (the potential Vsb of the substrate 101 is a positive potential), a potential is applied to each electrode so that more electrons (e⁻) and negative ions are emitted from the space 15 of plasma toward the substrate 101. Then, the electrification of the substrate 101 is reduced by the electrons (e⁻) and negative ions reaching the surface of the substrate 101. Alternatively/Also, the active species (O*) are emitted from the space 15 of plasma toward the substrate 101 and thus, impurities on the substrate 101 can be removed.

According to Embodiment 4, as described above, plasma by the Penning discharge or magnetron discharge can be generated without affecting the magnetic field generated by the electromagnetic lens (for example, the objective lens 607) constituting the electron beam optical system inherent to the apparatus that emits the multiple beams 20. Therefore, ions (for example, positive ions X⁺), electrons (e⁻), and active species (O*) can be generated and also, the electrification of the substrate 101 can be reduced or/and contaminants of the substrate 101 (the deflector 608) and the like can be removed. As a result, high-precision pattern writing can be performed.

In each of Embodiments described above, the retarding electrode may be configured as follows. Hereinafter, as an example, a description will be provided using a modification of the configuration in FIG. 5.

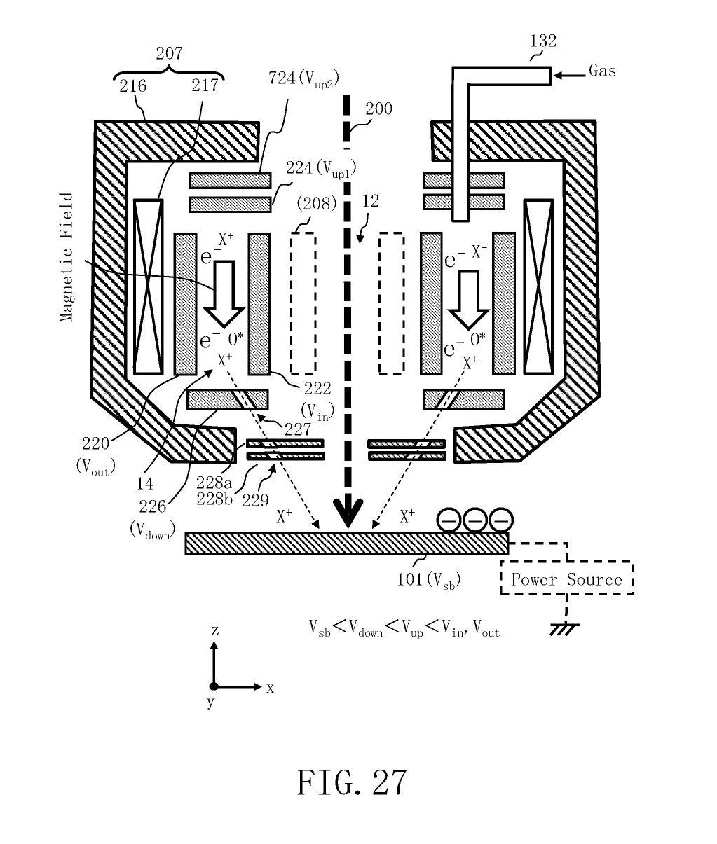

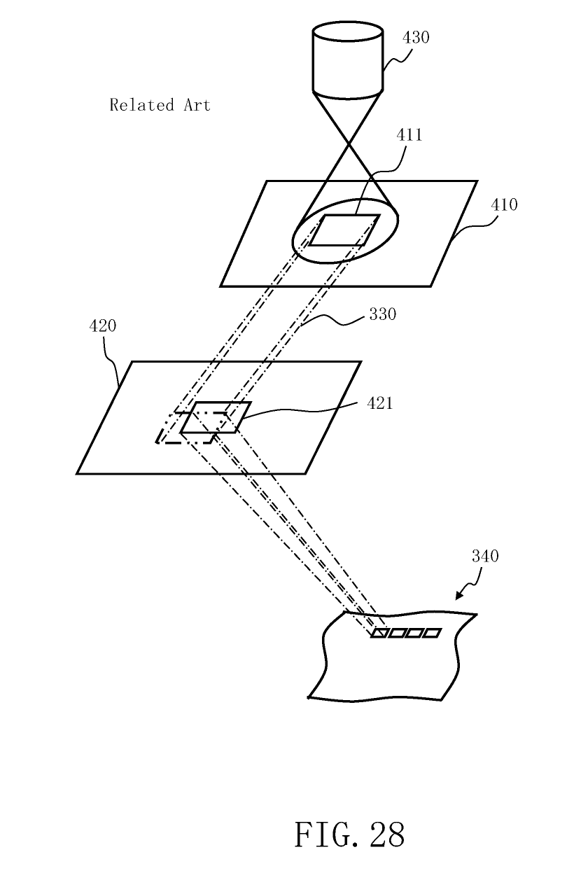

FIG. 27 is a sectional view showing a modification of the configuration in FIG. 5. As shown in FIG. 27, the retarding electrode 228 may have a multilayer structure to be able to control the outflow of charged particles. For example, by setting the electrode 228b facing the substrate 101 to the same potential as that of the substrate 101 and controlling the potential of the electrode 228a in a two-layer structure (228a, 228b from above), the emission of positive ions (X⁺) or electrons (e⁻) or negative ions can be controlled. Other configurations are the same as those in FIG. 5.

In the foregoing, Embodiments have been described with reference to concrete examples. However, the present disclosure is not limited to these concrete examples. In the examples described above, a case where a one-stage deflector 208 (608) is arranged as an objective deflector has been described, but the present disclosure is not limited to such examples. For example, multi-stage deflectors having different deflection regions may be arranged. In such a case, the present disclosure can also be applied to cleaning of multi-stage deflectors.

Portions of the apparatus configuration, the control method, and the like that are not needed directly for the description of the present disclosure omitted, but a necessary apparatus configuration or a necessary control method may be appropriately selected and used. For example, the description of the controller configuration that controls the lithography apparatus 100 (500) is omitted, but a necessary controller configuration is appropriately selected and used, as a matter of course.

In addition, all charged particle beam irradiation apparatuses and methods for reducing electrification of a substrate including the elements of the present invention and can be attained by appropriately changing in design by a person skilled in the art are included in the spirit and scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A charged particle beam irradiation apparatus comprising:
an emission source configured to emit a charged particle beam;
an electromagnetic lens configured to refract the charged particle beam;
a plurality of electrodes arranged in a magnetic field space of the electromagnetic lens and also arranged so as to surround a space on an outer side of a passing region of the charged particle beam; and
a potential control circuit configured to control potentials of the plurality of electrodes so as to generate plasma in the space surrounded by the plurality of electrodes and so as to control movement of positive ions or electrons and negative ions generated by the plasma, wherein
positive ions, electrons and negative ions, or active species are emitted from the space of the plasma.

2. The apparatus according to claim 1, wherein the plasma is generated by magnetron discharge.

3. The apparatus according to claim 1, wherein the plasma is generated by Penning discharge.

4. The apparatus according to claim 1, further comprising: a supply mechanism for supplying a gas to the space of the plasma.

5. The apparatus according to claim 1, wherein as the plurality of electrodes,
an inner electrode formed in a cylindrical shape,
an outer electrode formed in a cylindrical shape and arranged so as to surround an outer circumferential surface of the inner electrode,
an upper electrode formed like a disk in which an opening for passing the charged particle beam is formed at a central position and arranged above the outer electrode and the inner electrode so as to cover an upper portion of the space sandwiched between the outer electrode and the inner electrode, and
a lower electrode formed like a disk in which an opening for passing the charged particle beam is formed at a central position and arranged below the outer electrode and the inner electrode so as to cover a lower portion of the space sandwiched between the outer electrode and the inner electrode are used.

6. The apparatus according to claim 5, wherein a plurality of openings through which the positive ions, the electrons and the negative ions, or the active species are allowed to pass is formed in the lower electrode.

7. The apparatus according to claim 5, wherein the electromagnetic lens includes a coil and a pole piece surrounding the coil,
the outer electrode is arranged in a space between an upper surface portion and a lower surface portion of the pole piece, and
the inner electrode is arranged on an optical axis side than the pole piece and also on the outer side of the passing region of the charged particle beam.

8. The apparatus according to claim 1, wherein as the plurality of electrodes,
a plurality of ring electrodes arranged side by side in a circumferential direction,
an upper electrode arranged above the plurality of ring electrodes so as to cover an upper portion of the plurality of ring electrodes, and
a lower electrode arranged below the plurality of ring electrodes so as to cover a lower portion of the plurality of ring electrodes.

9. The apparatus according to claim 8, wherein the plurality of ring electrodes, the upper electrode, and the lower electrode are arranged so as to individually surround a plurality of spaces obtained by dividing the space on the outer side of the passing region of the charged particle beam.

10. A method for reducing electrification comprising:
controlling potentials of a plurality of electrodes arranged in a magnetic field space of an objective lens that focuses a charged particle beam on a substrate surface and also arranged so as to surround a space on an outer side of a passing region of the charged particle beam to cause the plurality of electrodes to generate plasma in the space surrounded by the plurality of electrodes and also to control movement of positive ions or electrons and negative ions generated by the plasma; and
reducing electrification of the substrate by allowing to emit the positive ions or the electrons and negative ions from the space of the plasma toward the substrate.
